(19) United States
(12) Patent Application Publication
(10) Pub. No.: US 2025/0261482 A1
(43) Pub. Date: Aug. 14, 2025

(54) LIGHT EMITTING ELEMENT

(71) Applicant: Samsung Display Co., LTD., Yongin-si (KR)

(72) Inventor: Seok Jin KANG, Yongin-si (KR)

(73) Assignee: Samsung Display Co., LTD., Yongin-si (KR)

(21) Appl. No.: 18/918,940

(22) Filed: Oct. 17, 2024

(30) Foreign Application Priority Data
Feb. 14, 2024 (KR) 10-2024-0021293

(51) Int. Cl. H01L 33/14; H01L 25/075; H01L 25/16; H01L 33/44

(52) U.S. Cl. CPC H10H 20/816; H01L 25/0753; H01L 25/167; H10H 20/84

(57) ABSTRACT

A light emitting element includes pillar structures which include a first semiconductor layer and an auxiliary layer disposed on the first semiconductor layer and are spaced apart from each other, an active layer disposed on the pillar structures, a second semiconductor layer disposed on the active layer, a first bonding electrode which is disposed below the pillar structures and is electrically connected to the first semiconductor layer, and a second bonding electrode which is disposed below the second semiconductor layer and is electrically connected to a non-overlapping surface of a bottom surface of the second semiconductor layer, which does not overlap the pillar structures and the active layer.

### CROSS-REFERENCE TO RELATED APPLICATION(S)

This application claims priority to and benefits of Korean patent application No. 10-2024-0021293 under 35 U.S.C. § 119(a), filed on Feb. 14, 2024 in the Korean Intellectual Property Office, the entire contents of which are incorporated herein by reference.

### BACKGROUND

### 1. Technical Field

This disclosure relates to a light emitting element.

### 2. Description of the Related Art

A light emitting element may receive a current injected thereinto to emit light. In order for the light emitting element to emit light with optimum efficiency, it is necessary to appropriately adjust a current density of the injected current. The current density means one obtained by dividing an intensity (e.g., expressed as a unit such as ampere (A)) of the injected current by an injection area (e.g., expressed as a unit such as cm²).

Due to various reasons, there are cases where it is difficult to increase the intensity of current injected into the light emitting element. For example, in a display device including a pixel to which a subminiature light emitting element (e.g., a micro LED) is applied, the number of transistors applicable to a pixel circuit may be limited.

Even in these cases, it is necessary to appropriately adjust the current density of injected current for the purpose of optimum efficiency of the light emitting element.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

In accordance with an aspect of the disclosure, there is provided a light emitting element. The light emitting element may include pillar structures including a first semiconductor layer and an auxiliary layer disposed on the first semiconductor layer, the pillar structures being spaced apart from each other, an active layer disposed on the pillar structures, a second semiconductor layer disposed on the active layer, a first bonding electrode disposed below the pillar structures, the first bonding electrode being electrically connected to the first semiconductor layer, and a second bonding electrode disposed below the second semiconductor layer, the second bonding electrode being electrically connected to a non-overlapping surface of a bottom surface of the second semiconductor layer, which does not overlap the pillar structures and the active layer.

The light emitting element may further include an insulative film covering at least a portion of an outer circumferential surface of a light emitting stack structure defined by the active layer and the second semiconductor layer.

The insulative film may expose bottom surfaces of the pillar structures. The first bonding electrode may electrically contact the bottom surfaces of the pillar structures.

The insulative film may define a penetration hole exposing at least a portion of the non-overlapping surface. The second bonding electrode may electrically contact the non-overlapping surface exposed by the penetration hole.

An area of the penetration hole in plan view may be smaller than an area of the second bonding electrode in plan view.

The insulative film may include a first insulative film and a second insulative film covering the first insulative film.

Side surfaces of the pillar structures may be covered by the first insulative film.

The second insulative film may have a multi-layer structure.

The first semiconductor layer may have a first polarity, and the second semiconductor layer may have a second polarity different from the first polarity.

A thickness of the auxiliary layer may be smaller than a thickness of the first semiconductor layer.

The thickness of the auxiliary layer may be in a range of about 1 nm to about 100 nm.

The second semiconductor layer may include a first doping portion disposed on the active layer and a second doping portion disposed on the first doping portion. A first average doping concentration at the first doping portion may be higher than a second average doping concentration at the second doping portion.

In accordance with another aspect of the disclosure, there is provided a light emitting element. The light emitting element may include pillar structures including a first semiconductor layer and an auxiliary layer disposed on the first semiconductor layer, the pillar structures being spaced apart from each other, an active layer disposed on the pillar structures, a second semiconductor layer disposed on the active layer, and a bonding electrode disposed below the pillar structures, the bonding electrode being electrically connected to the first semiconductor layer.

The light emitting element may further include an insulative film covering at least a portion of an outer circumferential surface of a light emitting stack structure defined by the active layer and the second semiconductor layer.

The insulative film may expose a top surface of the light emitting stack structure.

The insulative film may expose bottom surfaces of the pillar structures. The bonding electrode may electrically contact the bottom surfaces of the pillar structures.

The insulative film may include a first insulative film and a second insulative film covering the first insulative film.

Side surfaces of the pillar structures may be covered by the first insulative film.

The second insulative film may have a multi-layer structure.

A thickness of the auxiliary layer may be smaller than a thickness of the first semiconductor layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating a display device in accordance with embodiments of the disclosure.

FIG. 2 is a schematic block diagram illustrating any one sub-pixel among sub-pixels included in the display device shown in FIG. 1.

FIG. 3 is a schematic plan view illustrating a display panel constituting the display device shown in FIG. 1.

FIG. 4 is a schematic sectional view illustrating an embodiment of the display panel shown in FIG. 3.

FIG. 5 is a schematic sectional view illustrating another embodiment of the display panel shown in FIG. 3.

FIG. 6 is a schematic plan view illustrating an embodiment of a light emitting element included in a sub-pixel shown in FIG. 3.

FIG. 7 is a schematic sectional view taken along line X1-X1′ shown in FIG. 6.

FIG. 8 is a schematic sectional view taken along line Y1-Y1′ shown in FIG. 6.

FIGS. 9 to 15 are schematic views illustrating a method of manufacturing the light emitting element shown in FIG. 6.

FIG. 16 is a schematic plan view illustrating an embodiment of a pixel to which the light emitting element shown in FIG. 6 is applied.

FIG. 17 is a schematic sectional view taken along line Y2-Y2′ shown in FIG. 16.

FIG. 18 is a schematic sectional view taken along line X2-X2′ shown in FIG. 16.

FIG. 19 is a schematic plan view illustrating another embodiment of the pixel to which the light emitting element shown in FIG. 6 is applied.

FIG. 20 is a schematic sectional view taken along line Y3-Y3′ shown in FIG. 19.

FIG. 21 is a schematic sectional view taken along line X3-X3′ shown in FIG. 19.

FIG. 22 is a schematic plan view illustrating another embodiment of the light emitting element included in the sub-pixel shown in FIG. 3.

FIG. 23 is a schematic sectional view taken along line X4-X4′ shown in FIG. 22.

FIG. 24 is a schematic plan view illustrating an embodiment of a pixel to which the light emitting element shown in FIG. 22 is applied.

FIG. 25 is a schematic sectional view taken along line X5-X5′ shown in FIG. 24.

FIG. 26 is a schematic block diagram illustrating a display system in accordance with an embodiment of the disclosure.

FIGS. 27 to 30 are schematic perspective views illustrating application examples of the display system shown in FIG. 26.

### DETAILED DESCRIPTION OF THE EMBODIMENTS

Hereinafter, embodiments of the disclosure will be described in more detail with reference to the accompanying drawings. In the description below, only parts helpful to understand an operation according to the disclosure are described and the descriptions of other parts are omitted in order not to unnecessarily obscure subject matter of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

When an element is referred to as being “connected” or “coupled” to another element, it can be directly connected or coupled to the another element or be indirectly connected or coupled to the another element with one or more intervening elements interposed therebetween.

It will be understood that the terms “connected to” or “coupled to” may include a physical or electrical connection or coupling.

The technical terms used herein are used only for the purpose of illustrating a specific embodiment and not intended to limit the embodiment. It will be understood that when a component “comprises,” “has,” or “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

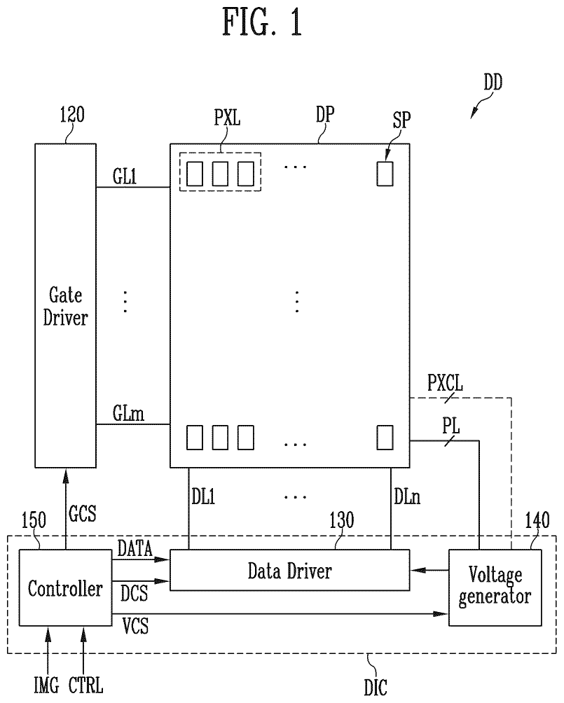

FIG. 1 is a schematic block diagram illustrating a display device in accordance with embodiments of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

The sub-pixels SP may generate lights of two or more colors. For example, each of the sub-pixels SP may generate lights of red, green, blue, cyan, magenta, yellow, white, and the like.

Two or more sub-pixels among the sub-pixels SP may constitute a pixel PXL. For example, the pixel PXL may include three sub-pixels as shown in FIG. 1. The pixel PXL may emit lights of various colors with various luminances according to a combination of lights emitted from the sub-pixels included in the pixel PXL.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal, and the like.

The gate driver 120 may be disposed at a side of the display panel DR However, embodiments are not limited thereto. For example, the gate driver 120 may be divided into two or more drivers which are physically and/or logically divided, and these drivers may be disposed at a side of the display panel DP and another side of the display panel DP, which may be opposite to the first side. As such, in some embodiments, the gate driver 120 may be disposed in various forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLm. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD. The voltage generator 140 may generate voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a predetermined or selected reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

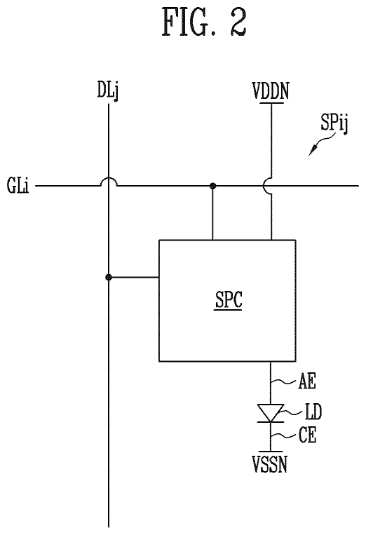

FIG. 2 is a schematic block diagram illustrating any one sub-pixel among the sub-pixels included in the display device shown in FIG. 1. In FIG. 2, a sub-pixel SPij arranged on an ith row (i is an integer which is greater than or equal to 1 and is smaller than or equal to m) and a jth column (j is an integer which is greater than or equal to 1 and is smaller than or equal to n) among the sub-pixels SP shown in FIG. 1 is illustrated merely as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an ith gate line GLi among the first to mth gate lines GL1 to GLm shown in FIG. 1 and a jth data line DLj among the first to nth data lines DL1 to DLn shown in FIG. 1. In response to a gate signal received through the ith gate line GLi, the sub-pixel circuit SPC may control the light emitting element LD to emit light according to a data signal received through the jth data line DLj. In embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. In embodiments, the transistors of the sub-pixel circuit SPC may include a Metal Oxide Silicon Field Effect Transistor (MOSFET). In embodiments, the transistors of the sub-pixel circuit SPC may include an amorphous silicon semiconductor, a monocrystalline silicon semiconductor, polycrystalline silicon semiconductor, an oxide semiconductor, and the like.

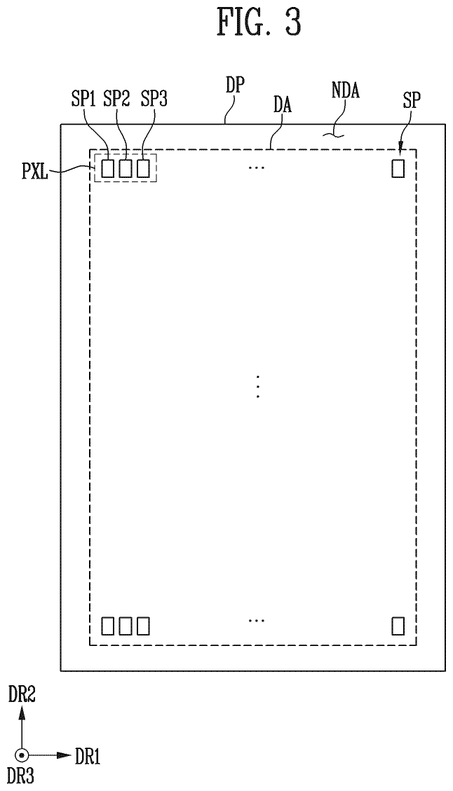

FIG. 3 is a schematic plan view illustrating the display panel constituting the display device shown in FIG. 1.

Referring to FIG. 3, a display panel DP may include a display area DA and a non-display area NDA. The display panel DP displays an image through the display area DA. The non-display area NDA may be disposed at the periphery of the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more sub-pixels among the sub-pixels SP may constitute one pixel PXL. In FIG. 3, it is illustrated that the pixel PXL includes three sub-pixels SP1, SP2, and SP3. However, embodiments are not limited thereto. For example, the pixel PXL may include two sub-pixels. Hereinafter, for convenience of description, it is assumed that the pixel PXL includes first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and simple description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1, SP2, and SP3 may include at least one light emitting element configured to generate light. In embodiments, light emitting elements of the first to third sub-pixels SP1, SP2, and SP3 may generate light of a same color. For example, the light emitting elements of the first to third sub-pixels SP1, SP2, and SP3 may generate light of a blue color. In other embodiments, the light emitting elements of the first to third sub-pixels SP1, SP2, and SP3 may generate lights of different colors. For example, the light emitting elements of the first to third sub-pixels SP1, SP2, and SP3 may generate lights of a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, e.g., the first to mth gate lines GL1 to GLm, the first to nth data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The data driver 130, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into one integrated circuit distinguished from the display panel DP.

In embodiments, the display area DA may have various shapes. The display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. The display panel DP and/or a substrate of the display panel DP may include materials having flexibility.

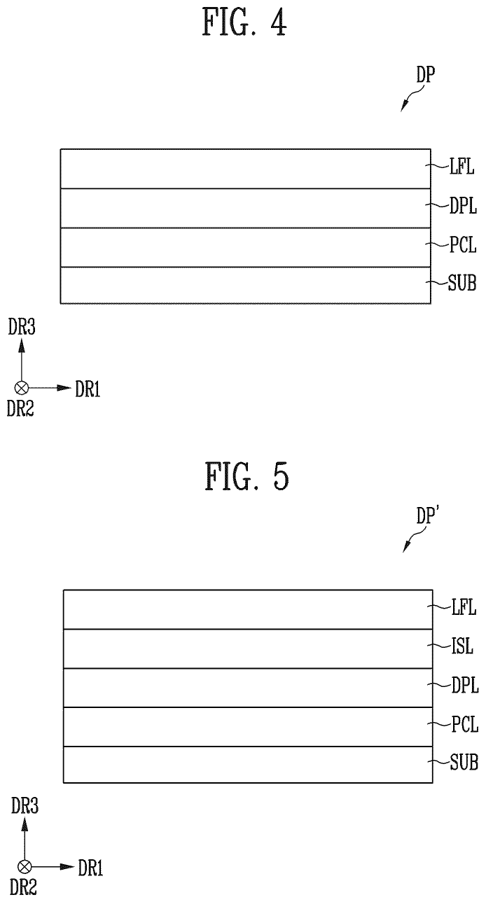

FIG. 4 is a schematic sectional view illustrating an embodiment of the display panel shown in FIG. 3.

Referring to FIG. 4, a display panel DP may include a substrate SUB, and a pixel circuit layer PCL, a display element layer DPL, and a light functional layer LFL, which are sequentially stacked on each other in a third direction DR3 intersecting the first and second directions DR1 and DR2 on the substrate SUB.

The substrate SUB may be made of an insulative material such as glass or resin. For example, the substrate SUB may include a glass substrate. In another example, the substrate SUB may include polyimide (PI) substrate. In still another example, the substrate SUB may include a silicon wafer substrate formed using a semiconductor process.

In embodiments, the substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

The circuit elements of the pixel circuit layer PCL may constitute a sub-pixel circuit SPC of each of the sub-pixels SP shown in FIG. 3. In other words, the circuit elements of the pixel circuit layer PCL may be provided as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines, which are for driving the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or light scattering particles. For example, color conversion particles may include quantum dots. The quantum dots may change a wavelength (or color) of light emitted from the display element layer DPL. The light functional layer LFL may further include light scattering patterns having light scattering particles. In embodiments, the light conversion patterns and the light scattering patterns may be omitted.

The light functional layer LFL may further include a color filter layer including color filters. The color filter may allow light having a specific wavelength (or specific color) to be selectively transmitted through the color filter. In embodiments, the color filter layer may be omitted.

A window for protecting an exposed surface (or top surface) of the display panel DP may be provided on the light functional layer LFL. The window may protect the display panel DP from external impact. The window may be bonded to the light functional layer LFL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

FIG. 5 is a schematic sectional view illustrating another embodiment of the display panel shown in FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured substantially identical (or similar) to the substrate SUB, the pixel circuit layer PCL, the display element layer DPL, and the light functional layer LFL, which are described with reference to FIG. 4, respectively. Therefore, redundant descriptions will be omitted.

The input sensing layer ISL may sense a user input with respect to a top surface (or display surface) of the display panel DP′. The input sensing layer ISL may include components suitable for sensing an external object such as a hand of a user or a pen. For example, the input sensing layer ISL may include touch electrodes.

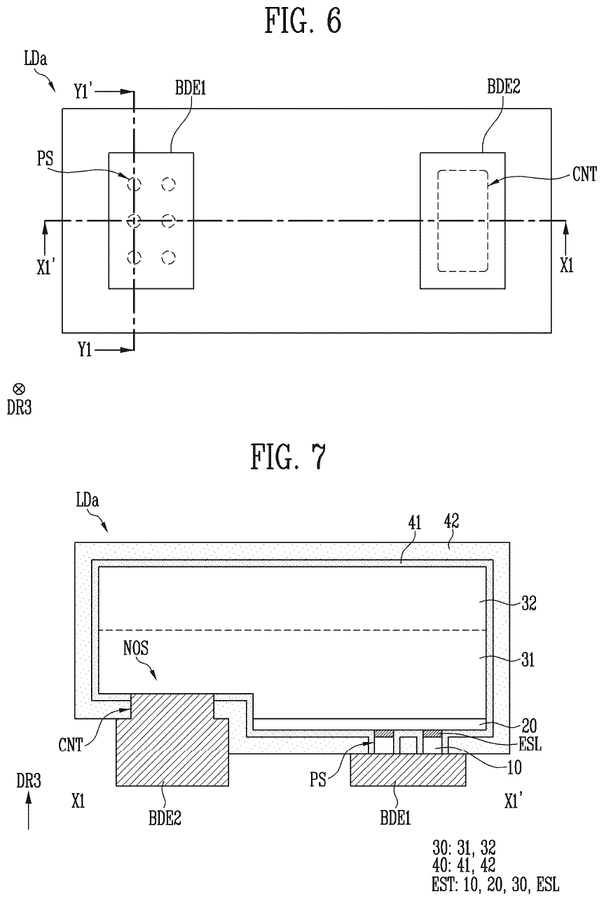

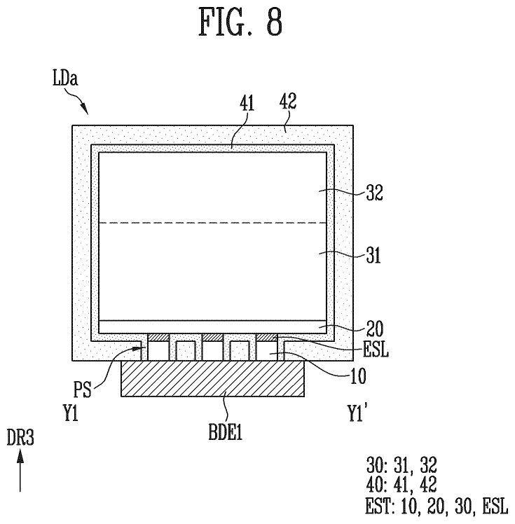

FIG. 6 is a schematic plan view illustrating an embodiment of a light emitting element included in the sub-pixel shown in FIG. 3. FIG. 7 is a schematic sectional view taken along line X1-X1′ shown in FIG. 6. FIG. 8 is a schematic sectional view taken along line Y1-Y1′ shown in FIG. 6.

Referring to FIGS. 6 to 8, a light emitting element LDa may include a light emitting stack structure EST, a first bonding electrode BDE1, a second bonding electrode BDE2, and an insulative film 40. The light emitting stack structure EST may include a first semiconductor layer 10, an auxiliary layer ESL, an active layer 20, and a second semiconductor layer 30, which are sequentially stacked on each other along the third direction DR3.

The first semiconductor layer 10 may be configured to provide holes. The first semiconductor layer 10 may have a first polarity. For example, the first semiconductor layer 10 may include at least one p-type semiconductor layer. For example, the first semiconductor layer 10 may include at least one semiconductor material among gallium nitride (GaN), aluminum gallium nitride (AlGaN), indium gallium nitride (InGaN), aluminum nitride (AlN), and indium nitride (InN), and be a p-type semiconductor layer doped with a first conductive dopant (or p-type dopant) such as magnesium (Mg), zinc (Zn), calcium (Ca), strontium (Sr), and barium (Ba). However, the material constituting the first semiconductor layer 10 is not limited thereto. Various materials may constitute the first semiconductor layer 10. In an embodiment of the disclosure, the first semiconductor layer 10 may include a gallium nitride (GaN) semiconductor material doped with the first conductive dopant (or n-type dopant).

The auxiliary layer ESL may be disposed on the first semiconductor layer 10. The auxiliary layer ESL may include a material having a high etch selectivity with respect to the active layer 20. Accordingly, the auxiliary layer ESL may protect the active layer 20 in an etching process of forming the light emitting element LDa. For example, in case that the active layer 20 is configured to emit light of a blue or green color, the auxiliary layer ESL may be made of AlₓGa₁₋ₓN (0≤X≤0.3). For example, in case that the active layer 20 is configured to emit light of a red color, the auxiliary layer ESL may be made of Al_{y}Ga_{1-y}As (0≤Y≤0.99). As such, the auxiliary layer ESL may be made of various materials according to the active layer 20.

The auxiliary layer ESL may be configured to substantially have no influence on element characteristics of the light emitting element LDa. For example, a carrier (e.g., hole) mobility or the like from the first semiconductor layer 10 to the active layer 20 may not be substantially changed by the auxiliary layer ESL. To this end, the auxiliary layer ESL may have a relatively small thickness. For example, a thickness of the auxiliary layer ESL in the third direction DR3 may be smaller than a thickness of the first semiconductor layer 10 in the third direction DR3. For example, the thickness of the auxiliary layer ESL in the third direction DR3 may be about 1 nm or more and about 100 nm or less.

One or more pillar structures PS may be defined, which includes the first semiconductor layer 10 and the auxiliary layer ESL. Each of the pillar structures PS may include the first semiconductor layer 10 and the auxiliary layer ESL disposed on the first semiconductor layer 10. The pillar structures PS may be spaced apart from each other. The pillar structures PS may have, for example, a cylindrical shape, but the disclosure is not limited thereto.

The active layer 20 may be disposed on the pillar structures PS. For example, the active layer 20 may contact the auxiliary layer ESL constituting top surfaces of the pillar structures PS. The active layer 20 may be disposed between the first semiconductor layer 10 and the second semiconductor layer 30 to provide an area in which electrons and holes are recombined. As electrons and holes are recombined in the active layer 20, light may be generated, which has a level changed to a low energy level and has a wavelength corresponding to the low energy level. The active layer 20 may be formed in a single quantum well structure or a multi-quantum well structure. In case that the active layer 20 is formed in the multi-quantum well structure, a unit including a barrier layer, a strain reinforcing layer, and a well layer may be repeatedly stacked on each other, to form the active layer 20. However, the active layer 20 is not limited to the above-described structure.

The active layer 20 may be made of various materials according to colors of light emitted from the active layer 20. For example, in case that the active layer 20 is configured to emit light of a blue or green color, the active layer 20 may include a barrier layer made of GaN and a well layer made of InGaN. For example, in case that the active layer 20 is configured to emit light of a red color, the active layer 20 may include a barrier layer made of AlGa_{z1}InP and a well layer made of Al_{z2}GaInP (Z1>Z2). The material constituting the auxiliary layer ESL may vary according to the material constituting the active layer 20, which may be the same as described above.

The second semiconductor layer 30 may be disposed on the active layer 20. For example, at least a portion of the second semiconductor layer 30 may contact a top surface of the active layer 20. The second semiconductor layer 30 may be configured to provide electrons. The second semiconductor layer 30 may have a second polarity different from the first polarity. For example, the second semiconductor layer 30 may include at least one n-type semiconductor layer. For example, the second semiconductor layer 30 may include at least one semiconductor material among gallium nitride (GaN), aluminum gallium nitride (AlGaN), indium gallium nitride (InGaN), aluminum nitride (AlN), and indium nitride (InN), and be an n-type semiconductor layer doped with a second conductive dopant (or n-type dopant) such as silicon (Si), germanium (Ge) or tin (Sn). However, the material constituting the second semiconductor layer 30 is not limited thereto. Various materials may constitute the second semiconductor layer 30. In an embodiment of the disclosure, the second semiconductor layer 30 may include a gallium nitride (GaN) semiconductor material doped with the second conductive dopant (or n-type dopant).

In some embodiments, the second semiconductor layer 30 may include a first doping portion 31 disposed on the active layer 20 and a second doping portion 32 disposed on the first doping portion 31. The first doping portion 31 may be an area doped with a dopant at a relatively high concentration. The second doping portion 32 may be area doped with the dopant at a relatively low concentration or substantially undoped with the dopant. For example, a first average doping concentration at the first doping portion 31 may be higher than a second average doping concentration at the second doping portion 32. The first doping portion 31 and the second doping portion 32 may be integrally formed, to define the second semiconductor layer 30.

The first bonding electrode BDE1 may be disposed below the pillar structures PS. The first bonding electrode BDE1 may be electrically connected to the first semiconductor layer 10. For example, the first bonding electrode BDE1 may contact the first semiconductor layer 10 constituting bottom surfaces of the pillar structures PS.

The second bonding electrode BDE2 may be disposed below the second semiconductor layer 30. The second bonding electrode BDE2 may be electrically connected to the second semiconductor layer 30. For example, the second bonding electrode BDE2 may be electrically connected to a non-overlapping surface NOS exposed as the active layer 20 or the like is etched. The non-overlapping surface NOS may constitute a portion of a bottom surface of the second semiconductor layer 30. Also, the non-overlapping surface NOS may not overlap the active layer 20 and the pillar structures PS.

In embodiments, the first bonding electrode BDE1 and the second bonding electrode BDE2 may include a eutectic metal.

The insulative film 40 may cover at least a portion of an outer circumferential surface of the light emitting stack structure EST. For example, the insulative film 40 may entirely cover the outer circumferential surface of the light emitting stack structure EST to expose at least a portion of the non-overlapping surface NOS of the second semiconductor layer 30 and the bottom surfaces of the pillar structures PS. The insulative film 40 may function to prevent an electrical short circuit which may occur in case that the active layer 20 contacts another conductive material except the first and second semiconductor layers 10 and 30.

In embodiments, a penetration hole CNT exposing at least a portion of the non-overlapping surface NOS may be defined. The second bonding electrode BDE2 may electrically contact the non-overlapping surface NOS exposed by the penetration hole CNT. An area of the penetration hole CNT in plan view may be smaller than an area of the second bonding electrode BDE2 in plan view.

In embodiments, the insulative film 40 may include a first insulative film 41 and a second insulative film 42. The first insulative film 41 may include a transparent insulating material. The first insulative film 41 may cover at least a portion of the outer circumferential surface of the light emitting stack structure EST. For example, side surfaces of the pillar structures PS may be covered by the first insulative film 41. The second insulative film 42 may include a transparent insulating material. The second insulative film 42 may cover the first insulative film 41. The second insulative film 42 may have a multi-layer structure. For example, the second insulative film 42 may have a multi-layer structure including insulative films having a thickness smaller than a thickness of the first insulative film. The second insulative film 42 may be configured to have a predetermined or selected thickness corresponding to a color of light emitted from the active layer 20. Accordingly, the second insulative film 42 may induce constructive interference of light emitted from the active layer 20, thereby improving the light emission efficiency of the light emitting element LDa.

A current (carrier, hole or the like) provided to the first bonding electrode BDE1 may be injected into the active layer 20 through the pillar structures PS. The pillar structures PS may adjust an injection area of the injected current, so that the light emission efficiency of the light emitting element LDa can be improved. For example, the light emitting element LDa may be a subminiature light emitting element (e.g., a micro LED). A current having a relatively low intensity may be supplied to the light emitting element LDa due to various factors such as limitation of a transistor constituting a pixel circuit SPC (see FIG. 2) connected to the light emitting element LDa. The number and/or area of pillar structures PS may be appropriately adjusted, thereby adjusting the injection area of the injected current. Accordingly, the light emitting element LDa can emit light with optimum efficiency in spite of the relatively low intensity of the injected current.

For example, in case that the intensity of the injected current is 1 micro ampere, current densities according to numbers of pillar structures PS having a cylindrical shape of which diameter is about 2 micrometers (when an area of each of the top and bottom surfaces, i.e., each of contact areas with the active layer 20 and the first bonding electrode BDE1 is about 3.14 μm²) may be represented by the following Table 1.

TABLE 1

| # of pillar structures (PS) | Current Density (A/cm²) |
|---|---|
| 1 | 31.8 |
| 2 | 15.9 |
| 3 | 10.6 |
| 4 | 8.0 |

Referring to Table 1, for example, in case that the active layer 20 of the light emitting element LDa is configured to emit light of a blue color, a current density of about 5 A/cm² to about 10 A/cm² may be required for the purpose of the optimum efficiency of the light emitting element LDa. The light emitting element LDa may be designed to have four pillar structures PS. In another example, in case that the active layer 20 of the light emitting element LDa is configured to emit light of a green color, a current density of about 30 A/cm² to about 40 A/cm² may be required for the purpose of the optimum efficiency of the light emitting element LDa. The light emitting element LDa may be designed to have one pillar structure PS.

However, the number, shape, and/or contact area of pillar structures PS of the disclosure are not limited to the aforementioned description. For example, the pillar structures PS may have an appropriate number, shape, and/or contact area for the optimum efficiency of the light emitting element LDa. In case that the sub-pixels SP1, SP2, and SP3 of the display panel DP (see FIG. 3) are configured to include light emitting elements emitting lights of different colors, numbers, shapes, and/or contact areas of pillar structures PS provided in the light emitting elements included in the respective sub-pixels SP1, SP2, and SP3 may be different from one another.

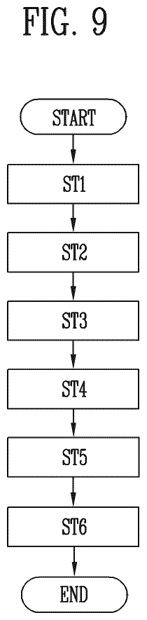

FIGS. 9 to 15 are schematic views illustrating a method of manufacturing the light emitting element shown in FIG. 6.

Referring to FIG. 9, the method of manufacturing the light emitting element LDa may include first to third steps ST1, ST2, ST3, ST4, ST5, and ST6. Hereinafter, descriptions of portions redundant to those described with reference to FIGS. 6 to 8 will be omitted.

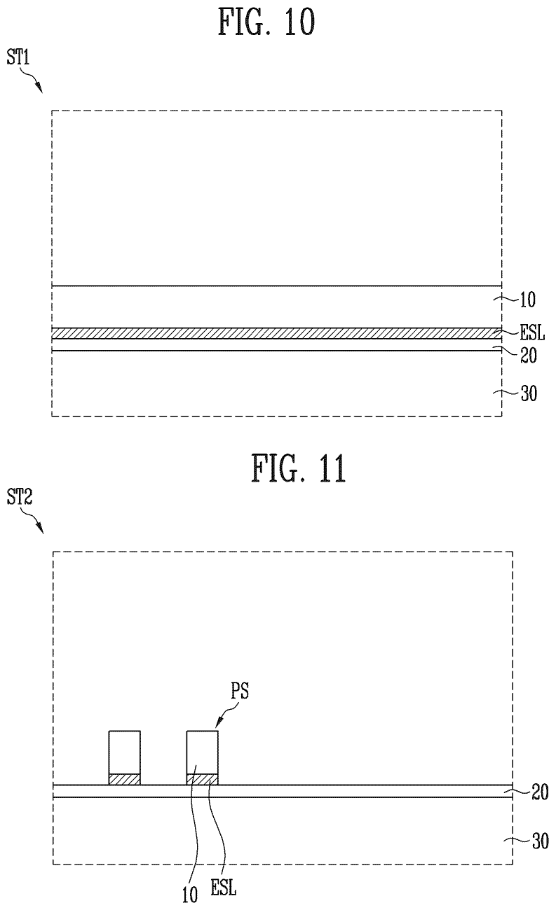

Referring to FIG. 10, a second semiconductor layer 30, an active layer 20, an auxiliary layer ESL, and a first semiconductor layer 10 may be sequentially provided (ST1). A method of providing the second semiconductor layer 30, the active layer 20, the auxiliary layer ESL, and the first semiconductor layer 10 is not limited, and various methods may be used. For example, a method of growing, on a semiconductor substrate, materials constituting the second semiconductor layer 30, the active layer 20, the auxiliary layer ESL, and the first semiconductor layer 10 may be used.

Referring to FIG. 11, pillar structures PS may be formed by patterning (e.g., selective etching) the first semiconductor layer 10 and the auxiliary layer ESL (ST2). The auxiliary layer ESL may serve as an etching protective layer for preventing damage of the active layer 20 in a selective etching process. Accordingly, the active layer 20 may not be damaged by the above-described selective etching process. For example, a top surface of the active layer 20 may be substantially flat after the selective etching process.

In some embodiments, the auxiliary layer ESL may be omitted in the first and second steps ST1 and ST2. For example, the first semiconductor layer 10 may be directly disposed on the active layer 20. A patterning process for forming each of the pillar structures PS may be performed to prevent damage of the active layer 20, for example, by finely adjusting conditions of the etching process. Each of the pillar structures PS may not include the auxiliary layer ESL, and be configured to include the first semiconductor layer 10.

Referring to FIG. 12, a portion of the second semiconductor layer 30 may be exposed by removing a portion of the active layer 20 (ST3). For example, a non-overlapping surface (see FIG. 7) of the second semiconductor layer 30 may be exposed.

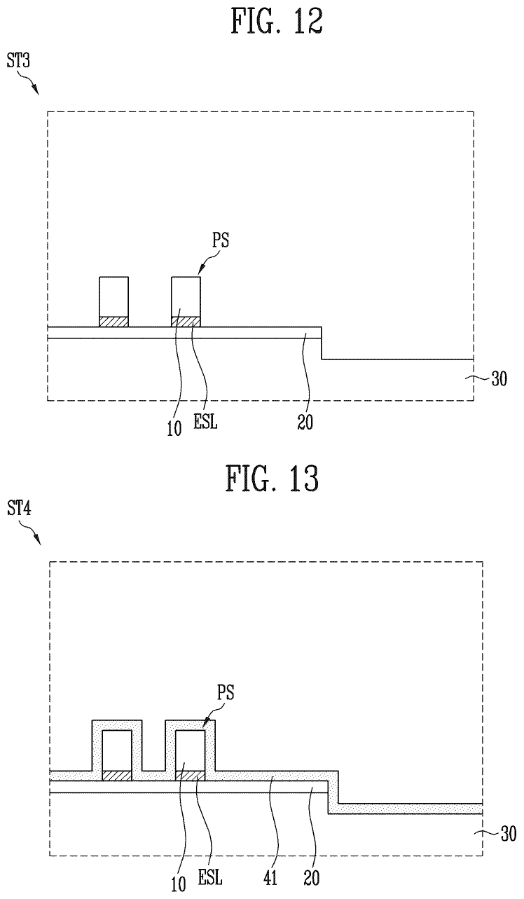

Referring to FIG. 13, a first insulative film 41 may be entirely formed (ST4). The first insulative film 41 may be formed using, for example, a CVD or ALD technique.

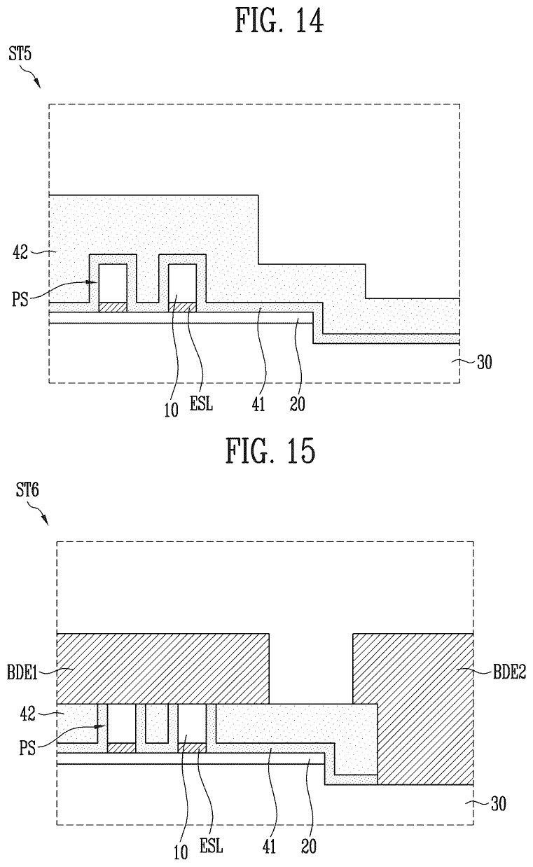

Referring to FIG. 14, a second insulative film 41 may be entirely formed (ST5). The second insulative film 42 may have a multi-layer structure. Insulative films included in the second insulative film 42 may be independently formed using an e-beam or sputter technique.

Referring to FIG. 15, portions of the first and second insulative films 41 and 42 may be removed, and a first bonding electrode BDE1 and a second bonding electrode BDE2 may be formed (ST6).

Accordingly, the first bonding electrode BDE1 may contact the first semiconductor layer 10 of each of the pillar structures PS, and the second bonding electrode BDE2 may contact the second semiconductor layer 30.

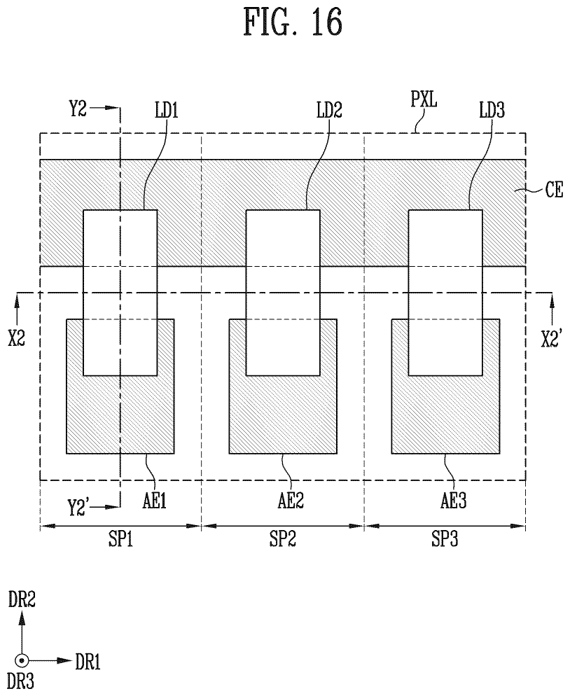

Hereinafter, an embodiment in which the light emitting element LDa is provided as a flip chip type light emitting element in the pixel PXL of the display panel DP (see FIG. 3) will be described with reference to FIGS. 16 to 18.

FIG. 16 is a schematic plan view illustrating an embodiment of a pixel to which the light emitting element shown in FIG. 6 is applied.

Referring to FIG. 16, a pixel PXL may include first to third sub-pixels SP1, SP2, and SP3. The first to third sub-pixels SP1, SP2, and SP3 may be arranged in the first direction DR1. However, the arrangement of the pixel PXL is not limited thereto, and may be variously changed in some embodiments. For example, the first to third sub-pixels SP1, SP2, and SP3 may be arranged in zigzag.

First to third anode electrodes AE1, AE2, and AE3 may be disposed in the first to third sub-pixels SP1, SP2, and SP3, respectively. The first anode electrode AE1 may be provided as an anode electrode AE (see FIG. 2) connected to a sub-pixel circuit SPC (see FIG. 2) of the first sub-pixel SP1. The second anode electrode AE2 may be provided as an anode electrode AE connected to a sub-pixel circuit SPC of the second sub-pixel SP2. The third anode electrode AE3 may be provided as an anode electrode AE connected to a sub-pixel circuit SPC of the third sub-pixel SP3.

A cathode electrode CE may be spaced apart from the first to third anode electrodes AE1, AE2, and AE3. The cathode electrode CE and the first to third anode electrodes AE1, AE2, and AE3 may be disposed at a same height. The cathode electrode CE may be spaced apart from the first to third anode electrodes AE1, AE2, and AE3 in the second direction DR2. In embodiments, the cathode electrode CE may extend in the first direction DR1, to be used as a common electrode of the pixel PXL and other pixels adjacent to the pixel PXL. Although not shown in the drawing, the cathode electrode CE may extend in the second direction DR2 in addition to the first direction DR1, to be used as a common electrode of all the sub-pixels SP shown in FIG. 3. As such, the cathode electrode CE may have various shapes.

First to third light emitting elements LD1, LD2, and LD3 may be disposed on the first to third anode electrodes AE1, AE2, and AE3 and the cathode electrode CE. The first light emitting element LD1 may be electrically connected to the first anode electrode AE1 and the cathode electrode CE. The first light emitting element LD1 may be provided as a light emitting element LD (see FIG. 2) connected to the sub-pixel circuit SPC of the first sub-pixel SP1. The second light emitting element LD2 may be electrically connected to the second anode electrode AE2 and the cathode electrode CE. The second light emitting element LD2 may be provided as a light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as a light emitting element LD connected to the sub-pixel circuit SPC of the third sub-pixel SP3.

The first light emitting element LD1, the second light emitting element LD2, and the third light emitting element LD3 may be configured substantially identical (or similar) to the light emitting element LDa described with reference to FIGS. 6 to 8.

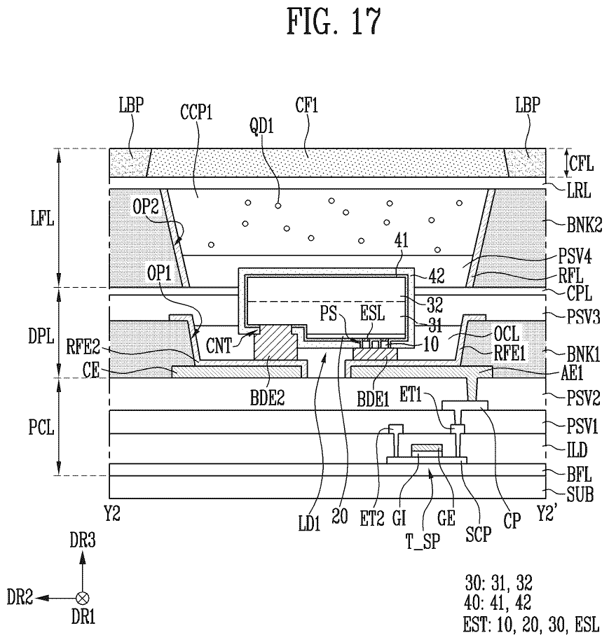

FIG. 17 is a schematic sectional view taken along line Y2-Y2′ shown in FIG. 16.

Referring to FIGS. 16 and 17, a pixel circuit layer PCL, a display element layer DPL, and a light functional layer LFL may be sequentially disposed on a substrate SUB.

The pixel circuit layer PCL may include insulating layers, semiconductor patterns, and conductive patterns, which are stacked on each other on the substrate SUB. The insulating layers may include a buffer layer BFL, one or more interlayer insulating layers ILD, and one or more passivation layers PSV1 and PSV2. The semiconductor patterns and the conductive patterns may be located between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1, SP2, and SP3 may include transistors and one or more capacitors. The semiconductor patterns and the conductive patterns of the pixel circuit layer PCL may serve as the transistors and the capacitors of the sub-pixel circuit SPC. The conductive patterns of the pixel circuit layer PCL may further serve as lines, e.g., the first to mth gate lines GL1 to GLm, the first to nth data lines DL1 to DLn, the power lines PL, and the pixel control lines PXCL, which are shown in FIG. 1.

The buffer layer BFL may be disposed on a surface of the substrate SUB. The buffer layer BFL may prevent an impurity from being diffused into circuit elements and lines, which are included in the pixel circuit layer PCL. The buffer layer BFL may include an inorganic insulating layer including an inorganic material. In embodiments, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer or a multi-layer. In case that the buffer layer BFL is provided as the multi-layer, layers of the multi-layer may be formed of a same material or be formed of different materials.

In embodiments, one or more barrier layers may be disposed between the substrate SUB and the buffer layer BFL. Each of the barrier layers may include polyimide.

A transistor T_SP may be disposed on the buffer layer BFL. The transistor T_SP may be any of the transistors of the sub-pixel circuit SPC included in the sub-pixel SP. For example, the transistor T_SP may be a transistor connected to the first anode electrode AE1 among the transistors of the sub-pixel circuit SPC.

The transistor T_SP may include a semiconductor pattern SCP, a gate electrode GE, a first terminal ET1, and a second terminal ET2. The first terminal ET1 may be any of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region contacting the first terminal ET1 and a second contact region contacting the second terminal ET2. A region between the first contact region and the second contact region may be a channel region. The channel region may overlap the gate electrode GE of the transistor T_SP. The channel region may be a semiconductor pattern substantially undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include at least one of various types of semiconductors, e.g., at least one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride, silicon oxide, silicon oxynitride, and a metal oxide such as aluminum oxide. However, the interlayer insulating layers ILD are not limited thereto. For example, any of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on the semiconductor pattern SCP and the buffer layer BFL, to cover the semiconductor pattern SCP and the buffer layer BFL. As the number of layers that may be required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP. The gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may contact the semiconductor pattern SCP through contact holes penetrating the interlayer insulating layers ILD. The first and second terminals ET1 and ET2 may contact the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

In embodiments, the transistor T_SP may be configured as a low temperature poly-silicon transistor. However, embodiments are not limited thereto. For example, the transistor T_SP may be configured as an oxide semiconductor transistor. In embodiments, the sub-pixel circuit of the first sub-pixel SP1 may include different types of transistors. For example, the transistor T_SP may be configured as a low temperature poly-silicon transistor, and another transistor of the first sub-pixel SP1 may be configured as an oxide semiconductor transistor. An oxide semiconductor of the corresponding oxide semiconductor transistor may be disposed on at least one of the interlayer insulating layers ILD instead of an insulating layer on which the semiconductor pattern SCP of the transistor T_SP.

In embodiments, a case where the transistor T_SP is a transistor having a top gate structure is described as an example. However, embodiments are not limited thereto. For example, the transistor T_SP may be a transistor having a bottom gate structure. The structure of the transistor T_SP may be variously changed.

At least a portion of various lines of the display panel DP and/or the display device DD may be further disposed on the interlayer insulating layers ILD.

A first passivation layer PSV1 may be disposed over the interlayer insulating layers ILD and the first and second terminals ET1 and ET2. The passivation layer may be designated as a protective layer or a via layer. The first passivation layer PSV1 may protect components disposed under the first passivation layer PSV1, and provide a flat top surface.

A connection pattern CP may be disposed on the first passivation layer PSV1. The connection pattern CP may be connected to the first terminal ET1 of the transistor T_SP while penetrating the first passivation layer PSV1. The connection pattern CP may include at least one material among copper (Cu), molybdenum (Mo), tungsten (W), aluminum neodymium (AlNd), titanium (Ti), aluminum (Al), and silver (Ag).

At least a portion of various lines of the display panel DP and/or the display device DD may be further disposed on the first passivation layer PSV1.

A second passivation layer PSV2 may be disposed over the connection pattern CP and the first passivation layer PSV1. The second passivation layer PSV2 may protect components disposed under the second passivation layer PSV2, and provide a flat top surface.

Each of the first and second passivation layers PSV1 and PSV2 may include an inorganic insulating layer including an inorganic material and/or an organic insulating layer including an organic material. The inorganic insulating layer may include, for example, at least one of silicon oxide, silicon nitride, silicon oxynitride, and a metal oxide such as aluminum oxide. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 may include a same material as at least one of the interlayer insulating layers ILD, but embodiments are not limited thereto. Each of the first and second passivation layers PSV1 and PSV2 may be provided as a single layer, but may also be provided as a multi-layer.

The display element layer DPL may be disposed on the second passivation layer PSV2. The display element layer DPL may include a first anode electrode AE1, a cathode electrode CE, a first bank BNK1, first and second reflective electrodes RFE1 and RFE2, a first light emitting element LD1, an overcoat layer OCL, a third passivation layer PSV3, and a capping layer CPL.

The first anode electrode AE1 and the cathode electrode CE may be disposed on the pixel circuit layer PCL.

The first anode electrode AE1 may be electrically connected to the connection pattern CP through a contact hole penetrating the second passivation layer PSV2. As such, the first anode electrode AE1 may be electrically connected to the transistor T_SP.

The cathode electrode CE may be spaced apart from the first anode electrode AE1 in the second direction DR1. The cathode electrode CE may be electrically connected to the second power voltage node VSSN shown in FIG. 2. Accordingly, the second power voltage applied to the second power voltage node VSSN may be transferred to the cathode electrode CE.

The first bank BNK1 may be disposed on the first anode electrode AE1 and the cathode electrode CE. The first bank BNK1 may have a first opening OP1 exposing portions of the first anode electrode AE1 and the cathode electrode CE. The first light emitting element LD1 may be disposed in the first opening OP1 of the first bank BNK1. As such, the first bank BNK1 may be provided as a pixel defining layer defining an area in which the first light emitting element LD1 is located.

The first bank BNK1 may be configured to include a light blocking material, to prevent light mixture between adjacent sub-pixels. In embodiments, the first bank BNK1 may include an organic material. For example, the first bank BNK1 may include an organic insulating material such as acrylic resin, epoxy resin, phenolic resin, polyamide resin, or polyimide resin.

The first reflective electrode RFE1 may be disposed on the exposed portion of the first anode electrode AE1 and a side surface of the first bank BNK1, which is adjacent thereto. The second reflective electrode RFE2 may be disposed on the exposed portion of the cathode electrode CE and a side surface of the first bank BNK1, which is adjacent thereto. The first and second reflective electrodes RFE1 and RFE2 may include conductive materials suitable for reflecting light. Accordingly, the light emission efficiency of the first light emitting element LD1 can be improved. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

The first light emitting element LD1 may be configured substantially identical (or similar) to the light emitting element LDa which has been described with reference to FIGS. 6 to 8. A first bonding electrode BDE1 of the first light emitting element LD1 may be electrically connected to the first anode electrode AE1 through the first reflective electrode RFE1. A second bonding electrode BDE2 may be electrically connected to the cathode electrode CE through the second reflective electrode RFE2. The first and second bonding electrodes BDE1 and BDE2 may be bonded to the first and second reflective electrodes RFE1 and RFE2, respectively. The first light emitting element LD1 may be a flip chip type light emitting element.

The overcoat layer OCL may be disposed in the first opening OP1 in which the first and second reflective electrodes RFE1 and RFE2 and the first light emitting element LD1 are disposed. The overcoat layer OCL may fix the first light emitting element LD1 bonded to the first and second reflective electrodes RFE1 and RFE2 not to move. Also, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed over the first bank BNK1 and the overcoat layer OCL. The third passivation layer PSV3 may protect components disposed under the third passivation layer PSV3, and provide a flat surface. The third passivation layer PSV3 and at least one of the first and second passivation layers PSV1 and PSV2 may include a same material, but embodiments are not limited thereto.

In embodiments, the third passivation layer PSV3 may not be disposed on a top surface of the first light emitting element LD1. The first light emitting element LD1 may protrude to the light functional layer LFL. The first light emitting element LD1 may be at least partially located in a second opening OP2 of a second bank BNK2. For example, a height of the top surface of the first light emitting element LD1 from the substrate SUB may be higher than a height of a lowermost end of a reflective layer RFL from the substrate SUB. Accordingly, light emitted from the first light emitting element LD1 may be provided to the light functional layer LFL at a relatively high ratio.

The capping layer CPL may be disposed on the third passivation layer PSV3. The capping layer CPL may protect components disposed under the capping layer CPL, such as the first light emitting element LD1, from external moisture, humidity, and the like. In embodiments, the capping layer CPL may not be disposed on the top surface of the first light emitting element LD1. In other embodiments, the capping layer CPL may entirely cover the first light emitting element LD1 and the third passivation layer PSV3. The capping layer CPL may include at least one of silicon nitride, silicon oxide, silicon oxynitride, and a metal oxide such as aluminum oxide. However, the material of the capping layer CPL is not limited thereto.

In the above, the pixel circuit layer PCL and the display element layer DPL of the first sub-pixel SP1 have been described. Each of the second and third sub-pixels SP2 and SP3 shown in FIG. 16 may also be configured substantially identically (or similar) to the first sub-pixel SP1.

The light functional layer LFL may be disposed on the capping layer CPL. The light functional layer LFL may include the second bank BNK2, the reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap the first bank BNK1. The second bank BNK2 may have the second opening OP2 overlapping the first opening OP1.

The second bank BNK2 may be configured to include a light blocking material, to prevent light mixture between adjacent sub-pixels. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the second opening OP2. The reflective layer RFL may be configured to reflect incident light, and accordingly, light emission efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 may be disposed in the second opening OP2. The fourth passivation layer PSV4 may protect components disposed under the fourth passivation layer PSV4, and provide a flat surface. The fourth passivation layer PSV4 and at least one of the first to third passivation layers PSV1, PSV2, and PSV3 may include a same material, but embodiments are not limited thereto.

On the fourth passivation layer PSV4, the first light conversion pattern CCP1 may be disposed in the second opening OP2.

The first light conversion pattern CCP1 may include color conversion particles and/or light scattering particles. The color conversion particles may convert incident light into light of another color by changing a wavelength of the incident light. Also, the color conversion particles may scatter incident light. In embodiments, the color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 configured to convert light of the blue color into light of a red color. In case that the first light emitting element LD1 emits light of the red color, the first light conversion pattern CCP1 may include light scattering particles. As such, the particles included in the first light conversion pattern CCP1 may be variously changed according to the first light emitting element LD1.

The low refractive layer LRL may be disposed on the second bank BNK2, the reflective layer RFL, and the first light conversion pattern CCP1. The low refractive layer LRL may have a refractive index lower than a refractive index of the first light conversion pattern CCP1. The low refractive layer LRL may be configured to refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 can be improved.

The color filter layer CFL may be disposed on the low refractive layer LRL. The color filter layer CFL may include a first color filter CF1 and light blocking patterns LBP. The first color filter CF1 may overlap the first light conversion pattern CCP1. The first color filter CF1 may allow light in a desired wavelength range to be selectively transmitted through the first color filter CF1. In case that the first sub-pixel SP1 is a red sub-pixel, the first color filter CF1 may include a red color filter. The light blocking patterns LBP may include at least one of various kinds of light blocking materials.

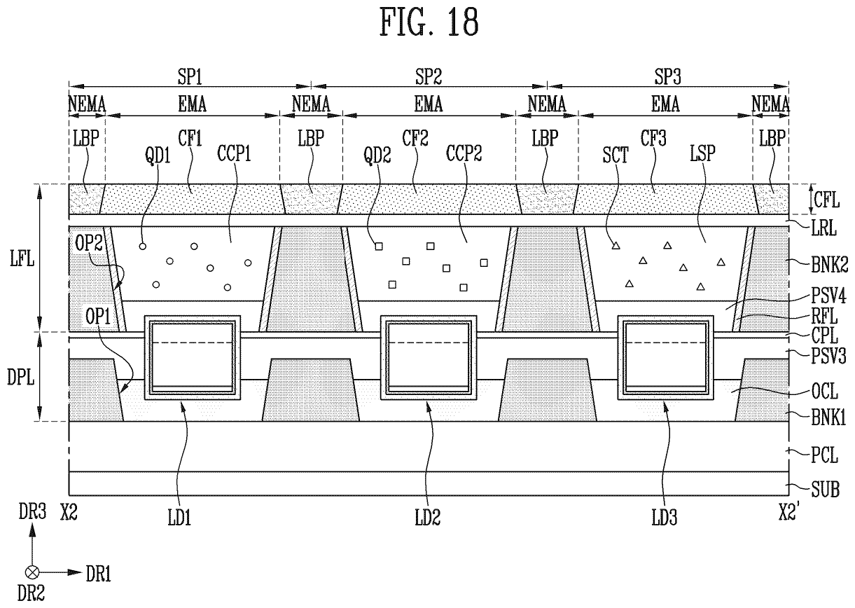

FIG. 18 is a schematic sectional view taken along line X2-X2′ shown in FIG. 16.

Referring to FIGS. 16 and 18, a pixel circuit layer PCL, a display element layer DPL, and a light functional layer LFL may be provided on a substrate SUB.

The pixel circuit layer PCL and the display element layer DPL may be the same as described with reference to FIG. 17. In the pixel circuit layer PCL, sub-pixel circuits respectively corresponding to the first to third sub-pixels SP1, SP2, and SP3 are provided. In the display element layer DPL, first to third light emitting elements LD1, LD2, and LD3 respectively corresponding to the first to third sub-pixels SP1, SP2, and SP3 may be provided. The first to third light emitting elements LD1, LD2, and LD3 may overlap first openings OP1 of a first bank BNK1. The first light emitting element LD1 may be connected between a cathode electrode CE (see FIG. 17) and a transistor T_SP (see FIG. 17) included in a sub-pixel circuit of the first sub-pixel SP1. The second light emitting element LD2 may be connected between the cathode electrode CE and a transistor included in a sub-pixel circuit of the second sub-pixel SP2. The third light emitting element LD3 may be connected between the cathode electrode CE and a transistor included in a sub-pixel circuit of the third sub-pixel SP3. Hereinafter, redundant descriptions will be omitted.

The light functional layer LFL may be provided on the display element layer DPL. The light functional layer LFL may be the same as described with reference to FIG. 17. Hereinafter, redundant descriptions will be omitted.

A second bank BNK2 may have second openings OP2. It may be understood that emission areas EMA and a non-emission area NEMA of the first to third sub-pixels SP1, SP2, and SP3 are defined by the second bank BNK2. An area overlapping the second bank BNK2 may correspond to the non-emission area NEMA. Areas overlapping the second openings OP2 of the second bank BNK2 may correspond to the emission areas EMA of the first to third sub-pixels SP1, SP2, and SP3.

On a capping layer CPL, a fourth passivation layer PSV4 may be disposed in the second openings OP2. On the fourth passivation layer PSV4, first and second light conversion patterns CCP1 and CCP2 and a light scattering pattern LSP may be disposed in the second openings OP2.

In embodiments, the first to third light emitting elements LD1, LD2, and LD3 may be configured to emit light of a blue color. The first light conversion pattern CCP1 may include first color conversion particles QD1 configured to convert light of the blue color into light of a red color. The second light conversion pattern CCP2 may include second color conversion particles QD2 configured to convert light of the blue color into light of a green color. The light scattering pattern LSP may include light scattering particles SCT which scatter light of the blue color so as to improve light emission efficiency. Accordingly, the first to third sub-pixels SP1, SP2, and SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion patterns which convert light of the blue color into light of a white color.

As described with reference to FIGS. 6 to 8 and Table 1, in case that the first to third light emitting elements LD1, LD2, and LD3 are configured to emit light of a same color (e.g., the blue color), numbers, shapes, and contact areas of pillar structures PS of the respective first to third light emitting elements LD1, LD2, and LD3 may be substantially the same.

In embodiments, the first to third light emitting elements LD1, LD2, and LD3 may be configured to emit lights of the red color, the green color, and the blue color, respectively. Each of the first and second light conversion patterns CCP1 and CCP2 and the light scattering pattern LSP may include the light scattering particles SCT. As such, the particles included in the first and second light conversion patterns CCP1 and CCP2 and the light scattering pattern LSP may be variously changed according to colors of lights emitted from the first to third light emitting elements LD1, LD2, and LD3.

As described with reference to FIGS. 6 to 8 and Table 1, in case that the first to third light emitting elements LD1, LD2, and LD3 are configured to emit lights of different colors, numbers, shapes, and contact areas of pillar structures PS of the respective first to third light emitting elements LD1, LD2, and LD3 may be different from one another.

In embodiments, the first and second light conversion patterns CCP1 and CCP2 and the light scattering pattern LSP may be omitted.

A low refractive layer LRL may be disposed on the second bank BNK2, a reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. In embodiments, the low refractive layer LRL may be omitted in an area corresponding to the third sub-pixel SP3.

A color filter layer CFL may be disposed on the low refractive layer LRL. The color filter layer CFL may include the first to third color filters CF1, CF2, and CF3 and light blocking patterns LBP.

Each of the first to third color filters CF1, CF2, and CF3 may allow light in a desired wavelength range to be selectively transmitted through the color filter. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1, CF2, and CF3 may have a refractive index higher than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas EMA and the non-emission area NEMA of the first and second sub-pixels SP1, SP2, and SP3 are defined by the light blocking patterns LBP. An area overlapping the light blocking patterns LBP may correspond to the non-emission area NEMA. Areas not overlapping the light blocking patterns LBP may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1, CF2, and CF3. For example, each of the light blocking patterns LBP may be formed as the first to third color filters CF1, CF2, and CF3 overlap each other. In another example, a light blocking pattern between the first and second color filters CF1 and CF2 among the light blocking patterns LBP may be formed as a multi-layer in which the first and second color filters CF1 and CF2 overlap each other, and a light blocking pattern between the second and third color filters CF2 and CF3 among the light blocking patterns LBP may be formed as a multi-layer in which the second and third color filters CF2 and CF3 overlap each other. A light blocking pattern between the first color filter CF1 and a third color filter CF3 of an adjacent pixel may be formed as a multi-layer in which the first and third color filters CF1 and CF3 overlap each other. As such, each of the first to third color filters CF1, CF2, and CF3 may extend to the non-emission area NEMA to form the light blocking patterns LBP.

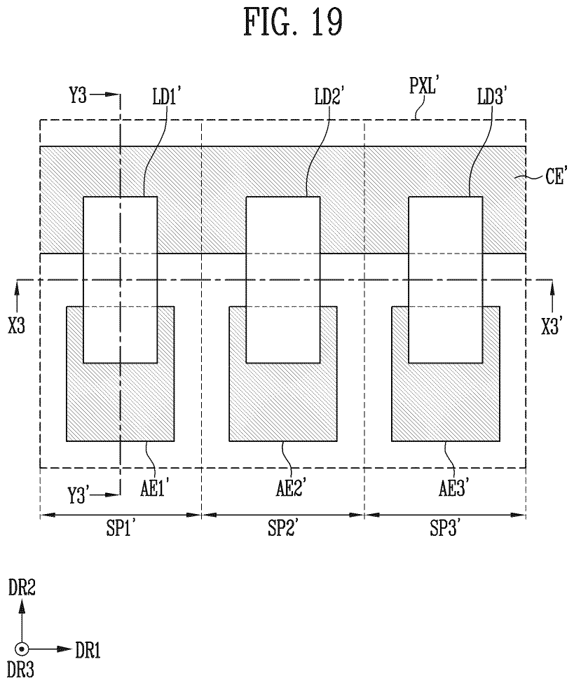

Hereinafter, an embodiment in which the light emitting element LDa is provided as a lateral type light emitting element in a pixel PXL′ of the display panel DP (see FIG. 3) will be described with reference to FIGS. 19 to 21.

FIG. 19 is a schematic plan view illustrating another embodiment of the pixel to which the light emitting element shown in FIG. 6 is applied.

Referring to FIG. 19, a pixel PXL′ may include first to third sub-pixels SP1′, SP2′, and SP3′. The first to third sub-pixels SP1′, SP2′, and SP3′ may be arranged in the first direction DR1. However, the arrangement of the pixel PXL′ is not limited thereto, and may be variously changed in some embodiments. For example, the first to third sub-pixels SP1′, SP2′, and SP3′ may be arranged in zigzag.

First to third anode electrodes AE1′, AE2′, and AE3′ may be disposed in the first to third sub-pixels SP1′, SP2′, and SP3′, respectively. The first anode electrode AE1′ may be provided as an anode electrode AE (see FIG. 2) of a sub-pixel circuit SPC (see FIG. 2) of the first sub-pixel SP1′. The second anode electrode AE2′ may be provided as an anode electrode AE of a sub-pixel circuit SPC of the second sub-pixel SP2′. The third anode electrode AE3 may be provided as an anode electrode AE of a sub-pixel circuit SPC of the third sub-pixel SP3′.

A cathode electrode CE′ may be spaced apart from the first to third anode electrodes AE1′, AE2′, and AE3′. The cathode electrode CE′ and the first to third anode electrodes AE1′, AE2′, and AE3′ may be disposed at a same height. The cathode electrode CE′ may be spaced apart from the first to third anode electrodes AE1′, AE2′, and AE3′ in the second direction DR2. In embodiments, the cathode electrode CE′ may extend in the first direction DR1, to be used as a common electrode of the pixel PXL′ and other pixels adjacent to the pixel PXL′. Although not shown in the drawing, the cathode electrode CE′ may extend in the second direction DR2 in addition to the first direction DR1, to be used as a common electrode of all the sub-pixels SP shown in FIG. 3. As such, the cathode electrode CE′ may have various shapes.

First to third light emitting elements LD1′, LD2′, and LD3′ may be disposed on the first to third anode electrodes AE1′, AE2′, and AE3′ and the cathode electrode CE′. The first light emitting element LD1′ may be electrically connected to the first anode electrode AE1′ and the cathode electrode CE′. The first light emitting element LD1′ may be provided as a light emitting element LD (see FIG. 2) connected to the sub-pixel circuit SPC of the first sub-pixel SP1′. The second light emitting element LD2′ may be electrically connected to the second anode electrode AE2′ and the cathode electrode CE′. The second light emitting element LD2′ may be provided as a light emitting element LD connected to the sub-pixel circuit SPC of the second sub-pixel SP2′. The third light emitting element LD3′ may be electrically connected to the third anode electrode AE3′ and the cathode electrode CE′. The third light emitting element LD3′ may be provided as a light emitting element LD connected to the sub-pixel circuit SPC of the third sub-pixel SP3′.

The first light emitting element LD1′, the second light emitting element LD2′, and the third light emitting element LD3′ may be configured substantially identical (or similar) to the light emitting element LDa described with reference to FIGS. 6 to 8.

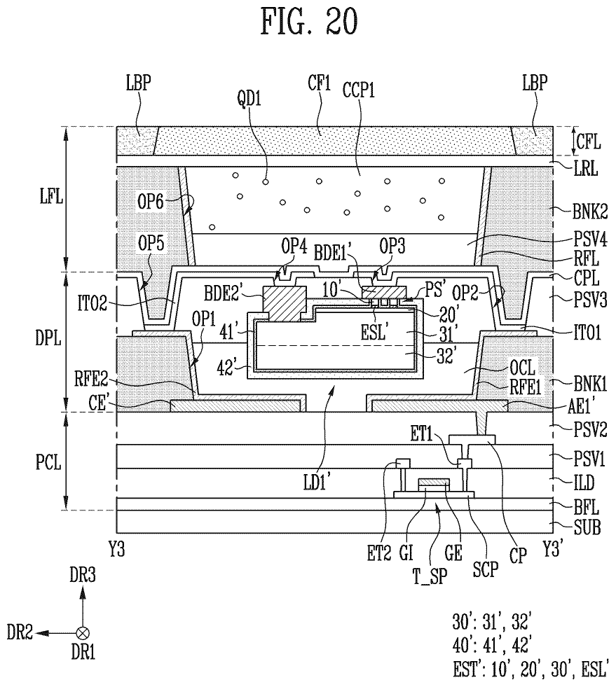

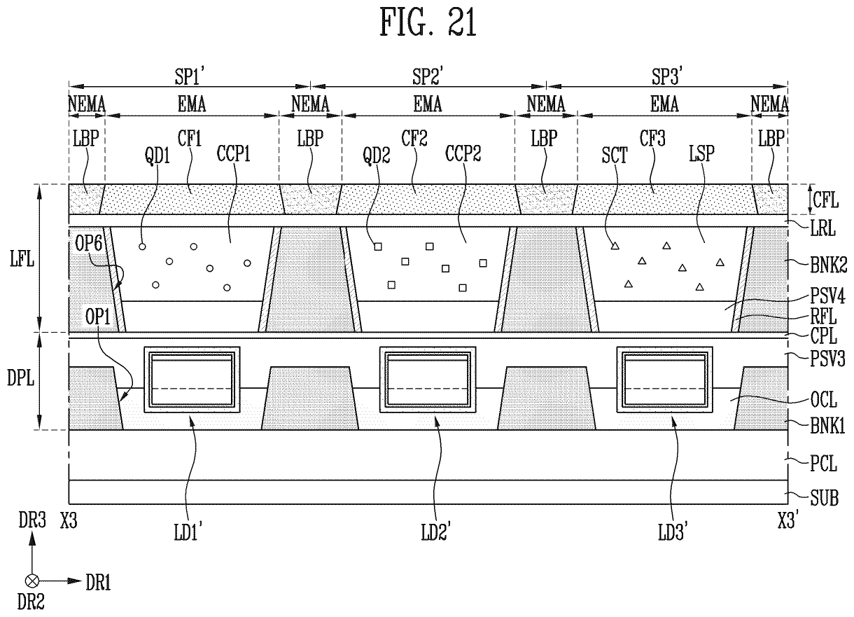

FIG. 20 is a schematic sectional view taken along line Y3-Y3′ shown in FIG. 19.

Referring to FIGS. 19 and 20, a pixel circuit layer PCL, a display element layer DPL, and a light functional layer LFL may be sequentially disposed on a substrate SUB.

The pixel circuit layer PCL may be configured substantially identically (or similar) as has described with reference to FIG. 17. Therefore, redundant descriptions will be omitted.

The display element layer DPL may be disposed on the pixel circuit layer PCL. The display element layer DPL may include a first anode electrode AE1′, a cathode electrode CE′, a first bank BNK1, first and second reflective electrodes RFE1 and RFE2, an overcoat layer OCL, a first light emitting element LD1′, a third passivation layer PSV3, first and second transparent electrodes ITO1 and ITO2, and a capping layer CPL.

The first anode electrode AE1′ and the cathode electrode CE′ may be disposed on the pixel circuit layer PCL.

The first anode electrode AE1′ may be electrically connected to a connection pattern CP through a contact hole penetrating a second passivation layer PSV2. As such, the first anode electrode AE1′ may be electrically connected to a transistor T_SP.

The cathode electrode CE′ may be spaced apart from the first anode electrode AE1′ in the second direction DR1. The cathode electrode CE′ may be electrically connected to the second power voltage node VSSN shown in FIG. 2. Accordingly, the second power voltage applied to the second power voltage node VSSN may be transferred to the cathode electrode CE′.

The first bank BNK1 may be disposed on the first anode electrode AE1′ and the cathode electrode CE′. The first bank BNK1 may have a first opening OP1 exposing portions of the first anode electrode AE1′ and the cathode electrode CE′. The first light emitting element LD1′ may be disposed in the first opening OP1 of the first bank BNK1. As such, the first bank BNK1 may be provided as a pixel defining layer defining an area in which the first light emitting element LD1′ is located.

The first bank BNK1 may be configured to include a light blocking material, to prevent light mixture between adjacent sub-pixels. In embodiments, the first bank BNK1 may include an organic material. For example, the first bank BNK1 may include an organic insulating material such as acrylic resin, epoxy resin, phenolic resin, polyamide resin, or polyimide resin.

The first reflective electrode RFE1 may be disposed on the exposed portion of the first anode electrode AE1′ and a side surface of the first bank BNK1, which is adjacent thereto. The second reflective electrode RFE2 may be disposed on the exposed portion of the cathode electrode CE′ and a side surface of the first bank BNK1, which is adjacent thereto. The first and second reflective electrodes RFE1 and RFE2 may include conductive materials suitable for reflecting light. Accordingly, the light emission efficiency of the first light emitting element LD1′ can be improved. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the first and second reflective electrodes RFE1 and RFE2 and the second passivation layer PSV2, the overcoat layer OCL may be disposed in the first opening OP1 of the first bank BNK1. The first light emitting element LD1′ may be disposed on the overcoat layer OCL. The first light emitting element LD1′ may be partially buried in the overcoat layer OCL.

The overcoat layer OCL may fix the first light emitting element LD1′ not to move. Also, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The first light emitting element LD1′ may be configured substantially identical (or similar) to the light emitting element LDa which has been described with reference to FIGS. 6 to 8. The first light emitting element LD1′ may be turned upside down such that the first and second bonding electrodes BDE1 and BDE2 of the light emitting element LDa face the third direction DR3. The first light emitting element LD1′ may be a lateral chip type light emitting element.

The third passivation layer PSV3 may be disposed over the first and second reflective electrodes RFE1 and RFE2, the first light emitting element LD1′, and the overcoat layer OCL. The third passivation layer PSV3 may protect components disposed under the third passivation layer PSV3, and provide a flat surface. The third passivation layer PSV3 and at least one of a first passivation layer PSV1 and the second passivation layer PSV2 may include a same material, but embodiments are not limited thereto.

The third passivation layer PSV3 may have second to fifth openings OP2, OP3, OP4, and OP5. The second opening OP2 may expose a portion of the first reflective electrode RFE1. The third opening OP3 may expose a top surface of a first bonding electrode BDE1′. The fourth opening OP4 may expose a top surface of a second bonding electrode BDE2′. The fifth opening OP5 may expose a portion of the second reflective electrode RFE2.

The first and second transparent electrodes ITO1 and ITO2 may be disposed on the third passivation layer PSV3. The first transparent electrode ITO1 may electrically connect the first reflective electrode RFE1 exposed by the second opening OP2 to the first bonding electrode BDE1′ exposed by the third opening OP3. The second transparent electrode ITO2 may electrically connect the second reflective electrode RFE2 exposed by the fifth opening OP5 to the second bonding electrode BDE2′ exposed by the fourth opening OP4. Accordingly, the first bonding electrode BDE1′ may be electrically connected to the first anode electrode AE1′ through the first transparent electrode ITO1 and the first reflective electrode RFE1. The second bonding electrode BDE2′ may be electrically connected to the cathode electrode CE′ through the second transparent electrode ITO2 and the second reflective electrode RFE2.

In embodiments, the first and second transparent electrodes ITO1 and ITO2 may be formed substantially transparent or translucent to satisfy a predetermined or selected light transmittance. In embodiments, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited thereto.

The capping layer CPL may be disposed on the third passivation layer PSV3. The capping layer CPL may protect components disposed under the capping layer CPL, such as the first and second transparent electrodes ITO1 and ITO2 and the first light emitting element LD1′, from external moisture, humidity, and the like. The capping layer CPL may include at least one of silicon nitride, silicon oxide, silicon oxynitride, and a metal oxide such as aluminum oxide. However, the material of the capping layer CPL is not limited thereto.

In the above, the pixel circuit layer PCL and the display element layer DPL of the first sub-pixel SP1′ have been described. Each of the second and third sub-pixels SP2′ and SP3′ shown in FIG. 19 may also be configured substantially identically (or similar) to the first sub-pixel SP1′.

The light functional layer LFL may be disposed on the capping layer CPL. The light functional layer LFL may include a second bank BNK2, a reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap the first bank BNK1. The second bank BNK2 may have a sixth opening OP6 overlapping the first opening OP1.

The second bank BNK2 may be configured to include a light blocking material, to prevent light mixture between adjacent sub-pixels. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the sixth opening OP6. The reflective layer RFL may be configured to reflect incident light, and accordingly, light emission efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 may be disposed in the sixth opening OP6. The fourth passivation layer PSV4 may protect components disposed under the fourth passivation layer PSV4, and provide a flat surface. The fourth passivation layer PSV4 and at least one of the first to third passivation layers PSV1, PSV2, and PSV3 may include a same material, but embodiments are not limited thereto.

On the fourth passivation layer PSV4, the first light conversion pattern CCP1 may be disposed in the sixth opening OP6.

The first light conversion pattern CCP1 may include color conversion particles and/or light scattering particles. The color conversion particles may convert incident light into light of another color by changing a wavelength of the incident light. Also, the color conversion particles may scatter incident light. In embodiments, the color conversion particles may be quantum dots. The light scattering particles may scatter incident light.

The first sub-pixel SP1′ may be a red sub-pixel. In case that the first light emitting element LD1′ emits light of a blue color, the first light conversion pattern CCP1 may include first color conversion particles QD1 configured to convert light of the blue color into light of a red color. In case that the first light emitting element LD1′ emits light of the red color, the first light conversion pattern CCP1 may include light scattering particles. As such, the particles included in the first light conversion pattern CCP1 may be variously changed according to the first light emitting element LD1′.

The low refractive layer LRL may be disposed on the second bank BNK2, the reflective layer RFL, and the first light conversion pattern CCP1. The low refractive layer LRL may have a refractive index lower than a refractive index of the first light conversion pattern CCP1. The low refractive layer LRL may be configured to refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 can be improved.

The color filter layer CFL may be disposed on the low refractive layer LRL. The color filter layer CFL may include a first color filter CF1 and light blocking patterns LBP. The first color filter CF1 may overlap the first light conversion pattern CCP1. The first color filter CF1 may allow light in a desired wavelength range to be selectively transmitted through the first color filter CF1. In case that the first sub-pixel SP1′ is a red sub-pixel, the first color filter CF1 may include a red color filter. The light blocking patterns LBP may include at least one of various kinds of light blocking materials.

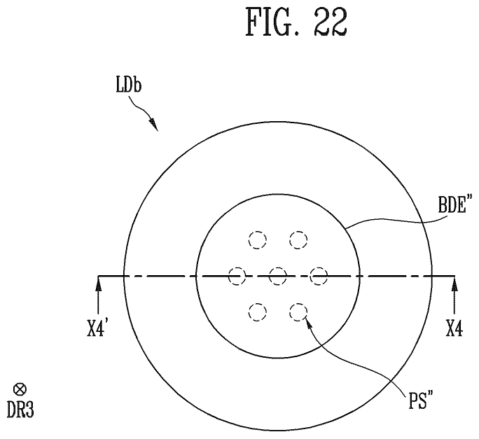

FIG. 21 is a schematic sectional view taken along line X3-X3′ shown in FIG. 19.

Referring to FIGS. 19 and 21, a pixel circuit layer PCL, a display element layer DPL, and a light functional layer LFL may be provided on a substrate SUB.

The pixel circuit layer PCL and the display element layer DPL may be the same as described with reference to FIG. 20. In the pixel circuit layer PCL, sub-pixel circuits respectively corresponding to the first to third sub-pixels SP1′, SP2′, and SP3′ are provided. In the display element layer DPL, first to third light emitting elements LD1′, LD2′, and LD3′ respectively corresponding to the first to third sub-pixels SP1′, SP2′, and SP3′ may be provided. The first to third light emitting elements LD1′, LD2′, and LD3′ may overlap first openings OP1 of a first bank BNK1. The first light emitting element LD1′ may be connected between a cathode electrode CE′ (see FIG. 20) and a transistor T_SP (see FIG. 20) included in a sub-pixel circuit of the first sub-pixel SP1′. The second light emitting element LD2′ may be connected between the cathode electrode CE′ and a transistor included in a sub-pixel circuit of the second sub-pixel SP2′. The third light emitting element LD3′ may be connected between the cathode electrode CE′ and a transistor included in a sub-pixel circuit of the third sub-pixel SP3′. Hereinafter, redundant descriptions will be omitted.

The light functional layer LFL may be provided on the display element layer DPL. The light functional layer LFL may be the same as described with reference to FIG. 19. Hereinafter, redundant descriptions will be omitted.

A second bank BNK2 may have sixth openings OP6. It may be understood that emission areas EMA and a non-emission area NEMA of the first to third sub-pixels SP1′, SP2′, and SP3′ are defined by the second bank BNK2. An area overlapping the second bank BNK2 may correspond to the non-emission area NEMA. Areas overlapping the sixth openings OP6 of the second bank BNK2 may correspond to the emission areas EMA of the first to third sub-pixels SP1′, SP2′, and SP3′.

On a capping layer CPL, a fourth passivation layer PSV4 may be disposed in the sixth openings OP6. On the fourth passivation layer PSV4, first and second light conversion patterns CCP1 and CCP2 and a light scattering pattern LSP may be disposed in the sixth openings OP6.

In embodiments, the first to third light emitting elements LD1′, LD2′, and LD3′ may be configured to emit light of a blue color. The first light conversion pattern CCP1 may include first color conversion particles QD1 configured to convert light of the blue color into light of a red color. The second light conversion pattern CCP2 may include second color conversion particles QD2 configured to convert light of the blue color into light of a green color. The light scattering pattern LSP may include light scattering particles SCT which scatter light of the blue color so as to improve light emission efficiency. Accordingly, the first to third sub-pixels SP1′, SP2′, and SP3′ may be provided as a red sub-pixel, a green sub-pixel, and a blue sub-pixel, respectively. In embodiments, at least one of the first and second light conversion patterns CCP1 and CCP2 and the light scattering pattern LSP may further include color conversion patterns which convert light of the blue color into light of a white color.

As described with reference to FIGS. 6 to 8 and Table 1, in case that the first to third light emitting elements LD1′, LD2′, and LD3′ are configured to emit light of a same color (e.g., the blue color), numbers, shapes, and contact areas of pillar structures PS' of the respective first to third light emitting elements LD1′, LD2′, and LD3′ may be substantially the same.

In embodiments, the first to third light emitting elements LD1′, LD2′, and LD3′ may be configured to emit lights of the red color, the green color, and the blue color, respectively. Each of the first and second light conversion patterns CCP1 and CCP2 and the light scattering pattern LSP may include the light scattering particles SCT. As such, the particles included in the first and second light conversion patterns CCP1 and CCP2 and the light scattering pattern LSP may be variously changed according to colors of lights emitted from the first to third light emitting elements LD1′, LD2′, and LD3′.

As described with reference to FIGS. 6 to 8 and Table 1, in case that the first to third light emitting elements LD1′, LD2′, and LD3′ are configured to emit lights of different colors, numbers, shapes, and contact areas of pillar structures PS' of the respective first to third light emitting elements LD1′, LD2′, and LD3′ may be different from one another.

In embodiments, the first and second light conversion patterns CCP1 and CCP2 and the light scattering pattern LSP may be omitted.

A low refractive layer LRL may be disposed on the second bank BNK2, a reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. In embodiments, the low refractive layer LRL may be omitted in an area corresponding to the third sub-pixel SP3′.

A color filter layer CFL may be disposed on the low refractive layer LRL. The color filter layer CFL may include the first to third color filters CF1, CF2, and CF3 and light blocking patterns LBP.

Each of the first to third color filters CF1, CF2, and CF3 may allow light in a desired wavelength range to be selectively transmitted through the color filter. In case that the first sub-pixel SP1′ is a red sub-pixel, the first color filter CF1 may include a red color filter. In case that the second sub-pixel SP2′ is a green sub-pixel, the second color filter CF2 may include a green color filter. In case that the third sub-pixel SP3′ is a blue sub-pixel, the third color filter CF3 may include a blue color filter. The first to third color filters CF1, CF2, and CF3 may have a refractive index higher than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas EMA and the non-emission area NEMA of the first and second sub-pixels SP1′, SP2′, and SP3′ are defined by the light blocking patterns LBP. An area overlapping the light blocking patterns LBP may correspond to the non-emission area NEMA. Areas not overlapping the light blocking patterns LBP may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1, CF2, and CF3. For example, each of the light blocking patterns LBP may be formed as the first to third color filters CF1, CF2, and CF3 overlap each other. In another example, a light blocking pattern between the first and second color filters CF1 and CF2 among the light blocking patterns LBP may be formed as a multi-layer in which the first and second color filters CF1 and CF2 overlap each other, and a light blocking pattern between the second and third color filters CF2 and CF3 among the light blocking patterns LBP may be formed as a multi-layer in which the second and third color filters CF2 and CF3 overlap each other. A light blocking pattern between the first color filter CF1 and a third color filter CF3 of an adjacent pixel may be formed as a multi-layer in which the first and third color filters CF1 and CF3 overlap each other. As such, each of the first to third color filters CF1, CF2, and CF3 may extend to the non-emission area NEMA to form the light blocking patterns LBP.

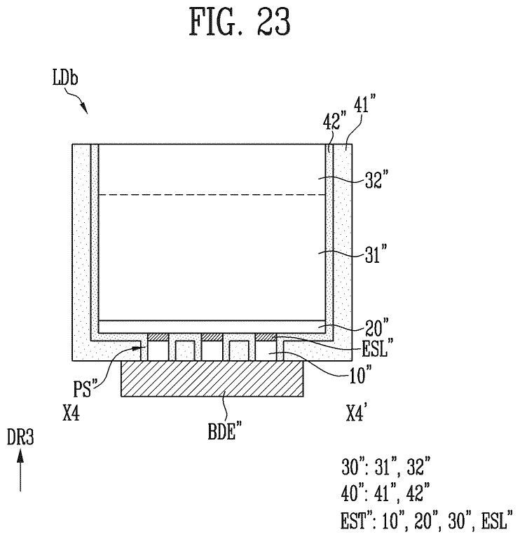

FIG. 22 is a schematic plan view illustrating another embodiment of the light emitting element included in the sub-pixel shown in FIG. 3. FIG. 23 is a schematic sectional view taken along line X4-X4′ shown in FIG. 22.

Referring to FIGS. 22 and 23, a light emitting element LDb may include a light emitting stack structure EST″, a bonding electrode BDE″, and an insulative film 40″. The light emitting stack structure EST″ may include a first semiconductor layer 10″, an auxiliary layer ESL″, an active layer 20″, and a second semiconductor layer 30″, which are sequentially stacked on each other along the third direction DR3.

The first semiconductor layer 10″ may be substantially identical (or similar) to the first semiconductor layer 10 which has been described with reference to FIGS. 6 to 8. Therefore, redundant descriptions will be omitted.

The auxiliary layer ESL″ may be substantially identical (or similar) to the auxiliary layer ESL which has been described with reference to FIGS. 6 to 8. Therefore, redundant descriptions will be omitted.

One or more pillar structures PS″ including the first semiconductor layer 10″ and the auxiliary layer ESL″ may be defined. Each of the pillar structures PS″ may include the first semiconductor layer 10″ and the auxiliary layer ESL″ disposed on the first semiconductor layer 10″. The pillar structures PS″ may be spaced apart from each other. The pillar structures PS″ may have, for example, a cylindrical shape, but the disclosure is not limited thereto.

The active layer 20″ may be disposed on the pillar structures PS″. The active layer 20″ may be substantially identical (or similar) to the active layer 20 which has been described with reference to FIGS. 6 to 8. Therefore, redundant descriptions will be omitted.

The second semiconductor layer 30″ may be disposed on the active layer 20″. The second semiconductor layer 30″ may be substantially identical (or similar) to the second semiconductor layer 30 which has been described with reference to FIGS. 6 to 8, except that the second semiconductor layer 30″ along with the active layer 20″ defines a pillar shape (e.g., a cylindrical shape). For example, a non-overlapping surface NOS (see FIG. 7) defined in the second semiconductor layer 30 may not be defined in the second semiconductor layer 30″. For example, the second semiconductor layer 30″ may include a first doping portion 31″ and a second doping portion 32″, and the first and second doping portions 31″ and 32″ may be substantially identical (or similar) to the first and second doping portions 31 and 32. Hereinafter, redundant descriptions will be omitted.

The bonding electrode BDE″ may be disposed below the pillar structures PS″. The bonding electrode BDE″ may be electrically connected to the first semiconductor layer 10″. For example, the bonding electrode BDE″ may contact the first semiconductor layer 10″ constituting bottom surfaces of the pillar structures PS″. The bonding electrode BDE″ may include a eutectic metal.

In some embodiments, a reflective electrode may be further disposed between the bonding electrode BDE″ and the pillar structures PS″. The reflective electrode may include a conductive material having a predetermined or selected reflectivity. Accordingly, the light emission efficiency of the light emitting element LDb can be improved.

The insulative film 40″ may cover at least a portion of an outer circumferential surface of the light emitting stack structure EST″. For example, the insulative film 40″ may entirely cover the outer circumferential surface of the light emitting stack structure EST″ to expose a top surface of the light emitting stack structure EST″ and the bottom surfaces of the pillar structures PS″. The insulative film 40″ may function to prevent a short circuit which may occur as the active layer 20″ contacts another conductive material except the first and second semiconductor layers 10″ and 20″.

In embodiments, the insulative film 40″ may include a first insulative film 41″ and a second insulative film 42″. The first and second insulative films 41″ and 42″ may be substantially identical (or similar) to the first and second insulative films 41 and 42 which have been described with reference to FIGS. 6 to 8. Therefore, redundant descriptions will be omitted.

A current (carrier, hole or the like) provided to the bonding electrode BDE″ may be injected into the active layer 20″ through the pillar structures PS″. The pillar structures PS″ may adjust an injection area of the injected current, so that the light emission efficiency of the light emitting element LDb can be improved. For example, the number, shape, and/or contact area of pillar structures PS″ may be appropriately adjusted. As such, the pillar structures PS″ may have a number, a shape, and/or a contact area, which are suitable for optimum efficiency of the light emitting element LDb. In case that the sub-pixels SP1, SP2, and SP3 of the display panel DP (see FIG. 3) are configured to include light emitting elements emitting lights of different colors, numbers, shapes, and/or contact areas of pillar structures PS″ provided in light emitting elements included in the respective sub-pixels SP1, SP2, and SP3 may be different from one another.

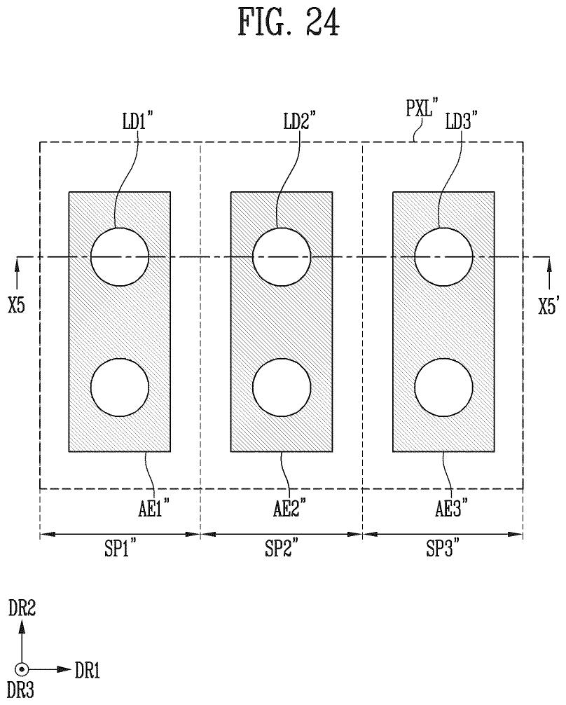

FIG. 24 is a schematic plan view illustrating an embodiment of a pixel to which the light emitting element shown in FIG. 22 is applied.

Referring to FIG. 24, a pixel PXL″ may include first to third sub-pixels SP1″, SP2″, and SP3″. The first to third sub-pixels SP1″, SP2″, and SP3″ may be arranged in the first direction DR1. However, the arrangement of the pixel PXL″ is not limited thereto, and may be variously changed in some embodiments. For example, the first to third sub-pixels SP1″, SP2″, and SP3″ may be arranged in zigzag.

First to third anode electrodes AE1″, AE2″, and AE3″ may be disposed in the first to third sub-pixels SP1″, SP2″, and SP3″, respectively. The first anode electrode AE1″ may be provided as an anode electrode AE included in a sub-pixel circuit SPC (see FIG. 2) of the first sub-pixel SP1″. The second anode electrode AE2″ may be provided as an anode electrode AE included in a sub-pixel circuit SPC of the second sub-pixel SP2″. The third anode electrode AE3″ may be provided as an anode electrode AE included in a sub-pixel circuit SPC of the third sub-pixel SP3″.

One or more first light emitting elements LD1″, one or more second light emitting elements LD2″, and one or more third light emitting elements LD3″ may be disposed on the first to third anode electrodes AE1″, AE2″, and AE3″, respectively. The first light emitting elements LD1″ may be connected to the first anode electrode AE1″. The second light emitting elements LD2″ may be connected to the second anode electrode AE2″. The third light emitting elements LD3″ may be connected to the third anode electrode AE3″. In case that multiple light emitting elements are provided in each sub-pixel, each anode electrode may have a shape extending in a specific direction such as the second direction DR2, and light emitting elements connected to the corresponding anode electrode may be arranged in the same direction.

The first light emitting elements LD1″ may be provided as a light emitting element LD (see FIG. 2) included in the first sub-pixel SP1″. The second light emitting elements LD2″ may be provided as a light emitting element LD (see FIG. 2) included in the second sub-pixel SP2″. The third light emitting elements LD3″ may be provided as a light emitting element LD (see FIG. 2) included in the third sub-pixel SP3″. In case that multiple light emitting elements are provided in one sub-pixel, the light emitting elements may be connected in parallel between an anode electrode and a cathode electrode to be provided as the light emitting element LD shown in FIG. 2.

Each of the first light emitting elements LD1″, the second light emitting elements LD2″, and the third light emitting elements LD3″ may be configured substantially identical (or similar) to the light emitting element LDb which has been described with reference to FIGS. 22 and 23.

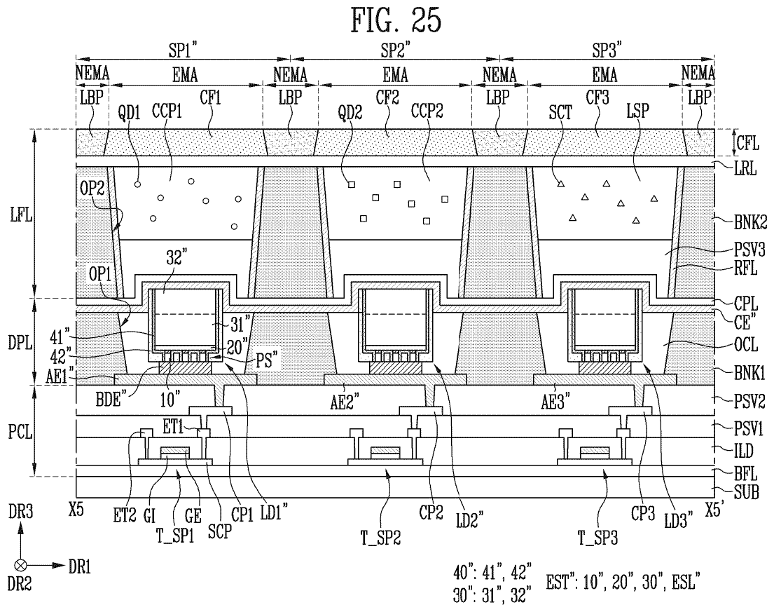

FIG. 25 is a schematic sectional view taken along line X5-X5′ shown in FIG. 24.

Referring to FIGS. 24 and 25, a pixel circuit layer PCL, a display element layer DPL, and a light functional layer LFL may be sequentially disposed on a substrate SUB.

The pixel circuit layer PCL may include insulating layers, semiconductor patterns, and conductive patterns, which are stacked on each other on the substrate SUB. The insulating layers may include a buffer layer BFL, one or more interlayer insulating layers ILD, and one or more passivation layers PSV1 and PSV2. The semiconductor patterns and the conductive patterns may be located between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1″, SP2″, and SP3″ may include transistors and one or more capacitors. The semiconductor patterns and the conductive patterns of the pixel circuit layer PCL may serve as the transistors and the capacitors of the sub-pixel circuit SPC. The conductive patterns of the pixel circuit layer PCL may further serve as lines, e.g., the first to mth gate lines GL1 to GLm, the first to nth data lines DL1 to DLn, the power lines PL, and the pixel control lines PXCL, which are shown in FIG. 1.

The buffer layer BFL may be disposed on a surface of the substrate SUB. The buffer layer BFL may prevent an impurity from being diffused into circuit elements and lines, which are included in the pixel circuit layer PCL. The buffer layer BFL may include an inorganic insulating layer including an inorganic material. In embodiments, the buffer layer BFL may include at least one of silicon nitride, silicon oxide, silicon oxynitride, and a metal oxide such as aluminum oxide. The buffer layer BFL may be provided as a single layer or a multi-layer. In case that the buffer layer BFL is provided as the multi-layer, layers of the multi-layer may be formed of the same material or be formed of different materials.

In embodiments, one or more barrier layers may be disposed between the substrate SUB and the buffer layer BFL. Each of the barrier layers may include polyimide.

First to third transistors T_SP1, T_SP2, and T_SP3 respectively corresponding to the first to third sub-pixels SP1″, SP2″, and SP3″ may be disposed on the buffer layer BFL. The first transistor T_SP1 may be any of transistors of a sub-pixel circuit SPC included in the first sub-pixel SP1″. The second transistor T_SP2 may be any of transistors of a sub-pixel SPC included in the second sub-pixel SP2″. The third transistor T_SP3 may be any of transistors of a sub-pixel circuit SPC included in the third sub-pixel SP3″. Each of the first to third transistors T_SP1, T_SP2, and T_SP3 may be understood as a transistor connected to an anode electrode among transistors of a corresponding sub-pixel.

The first transistor T_SP1 may include a semiconductor pattern SCP, a gate electrode GE, a first terminal ET1, and a second terminal ET2. The first terminal ET1 may be any of a source electrode and a drain electrode, and the second terminal ET2 may be the other of the source electrode and the drain electrode. For example, the first terminal ET1 may be the source electrode, and the second terminal ET2 may be the drain electrode. The first transistor T_SP1 may be configured substantially identical (or similar) to the transistor T_SP which has been described with reference to FIG. 17. The second and third transistors T_SP2 and T_SP3 may be configured substantially identical (or similar) to the first transistor T_SP1. Therefore, redundant descriptions will be omitted.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on the semiconductor pattern SCP and the buffer layer BFL, to cover the semiconductor pattern SCP and the buffer layer BFL. As the number of layers that may be required to form the conductive patterns and/or the semiconductor patterns increases, the number of interlayer insulating layers ILD may increase.

At least a portion of various lines of the display panel DP and/or the display device DD may be further disposed on the interlayer insulating layers ILD.

A first passivation layer PSV1 may be disposed over the interlayer insulating layers ILD and the first and second terminals ET1 and ET2. The passivation layer may be designated as a protective layer or a via layer. The first passivation layer PSV1 may protect components disposed under the first passivation layer PSV1, and provide a flat top surface.

First to third connection patterns CP1, CP2, and CP3 may be disposed on the first passivation layer PSV1. The first to third connection patterns CP1, CP2, and CP3 may be respectively connected to first terminals ET1 of the first to third transistors T_SP1, T_SP2, and T_SP3 while penetrating the first passivation layer PSV1. The first to third connection patterns CP1, CP2, and CP3 may include at least one material among copper (Cu), molybdenum (Mo), tungsten (W), aluminum neodymium (AlNd), titanium (Ti), aluminum (Al), and silver (Ag).

At least a portion of various lines of the display panel DP and/or the display device DD may be further disposed on the first passivation layer PSV1.

A second passivation layer PSV2 may be disposed over the first to third connection patterns CP1, CP2, and CP3 and the first passivation layer PSV1. The second passivation layer PSV2 may protect components disposed under the second passivation layer PSV2, and provide a flat top surface.

Each of the first and second passivation layers PSV1 and PSV2 may include an inorganic insulating layer including an inorganic material and/or an organic insulating layer including an organic material. The inorganic insulating layer may include, for example, at least one of silicon oxide, silicon nitride, silicon oxynitride, and a metal oxide such as aluminum oxide. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 and at least one of the interlayer insulating layers ILD may include a same material, but embodiments are not limited thereto. Each of the first and second passivation layers PSV1 and PSV2 may be provided as a single layer, but be provided as a multi-layer.

The display element layer DPL may be disposed on the second passivation layer PSV2. The display element layer DPL may include first to third anode electrodes AE1″, AE2″, and AE3″, a first bank BNK1, first to third light emitting elements LD1″, LD2″, and LD3″, an overcoat layer OCL, a cathode electrode CE″, and a capping layer CPL.

On the pixel circuit layer PCL, the first to third anode electrodes AE1″, AE2″, and AE3″ may be disposed in the first to third sub-pixels SP1″, SP2″, and SP3″, respectively.

The first anode electrode AE1″ may be electrically connected to the first connection pattern CP1 through a contact hole penetrating the second passivation layer PSV2. The second anode electrode AE2″ may be electrically connected to the second connection pattern CP2 through another contact hole penetrating the second passivation layer PSV2. The third anode electrode AE3″ may be electrically connected to the third connection pattern CP3 through still another contact hole penetrating the second passivation layer PSV2. As such, the first to third anode electrodes AE1″, AE2″, and AE3″ may be electrically connected to the first to third transistors T_SP1, T_SP2, and T_SP3, respectively.

The first bank BNK1 may be disposed on the first to third anode electrodes AE1″, AE2″, and AE3″. The first bank BNK1 may have first openings OP1 exposing portions of the first to third anode electrodes AE1″, AE2″, and AE3″. The first to third light emitting elements LD1″, LD2″, and LD3″ may be disposed in the first openings OP1 of the first bank BNK1. As such, the first bank BNK1 may be provided as a pixel defining layer defining areas in which the first to third light emitting elements LD1″, LD2″, and LD3″ are located.

The first bank BNK1 may be configured to include a light blocking material, to prevent light mixture between adjacent sub-pixels. In embodiments, the first bank BNK1 may include an organic material. For example, the first bank BNK1 may include an organic insulating material such as acrylic resin, epoxy resin, phenolic resin, polyamide resin, or polyimide resin. In order to further improve light emission efficiency, a reflective layer including a reflective material may be further disposed on side surfaces of the first bank BNK1, which are adjacent to the first openings OP1.

The first to third light emitting elements LD1″, LD2″, and LD3″ may be disposed on the first to third anode electrodes AE1″, AE2″, and AE3″, respectively. Bonding electrodes BDE″ of the first to third light emitting elements LD1″, LD2″, and LD3″ may be bonded to the first to third anode electrodes AE1″, AE2″, and AE3″, respectively.

The first light emitting element LD1″, the second light emitting element LD2″, and the third light emitting element LD3″ may be substantially identical (or similar) to the light emitting element LDb which has been described with reference to FIGS. 22 and 23.

The overcoat layer OCL may be disposed in the first openings OP1 in which the first to third light emitting elements LD1″, LD2″, and LD3″ are disposed. The overcoat layer OCL may fix the first to third light emitting elements LD1″, LD2″, and LD3″ bonded to the first to third anode electrodes AE1″, AE2″, and AE3″ not to move. Also, the overcoat layer OCL may protect components disposed under the overcoat layer OCL from a foreign matter such as dust or moisture. For example, the overcoat layer OCL may include at least one of an inorganic insulating layer and an organic insulating layer. For example, the overcoat layer OCL may include epoxy, but embodiments are not limited thereto.

In embodiments, the overcoat layer OCL may not be disposed on a top surface of each of the first to third light emitting elements LD1″, LD2″, and LD3″. The first to third light emitting elements LD1″, LD2″, and LD3″ may protrude to the light functional layer LFL. The first to third light emitting elements LD1″, LD2″, and LD3″ may be at least partially located in second openings OP2 of a second bank BNK2. For example, a height of the top surface of each of the first to third light emitting elements LD1″, LD2″, and LD3″ from the substrate SUB may be higher than a height of a lowermost end of a reflective layer RFL from the substrate SUB. Accordingly, light emitted from the first to third light emitting elements LD1″, LD2″, and LD3″ may be provided to the light functional layer LFL at a relatively high ratio.

The cathode electrode CE″ may be disposed on the first to third light emitting elements LD1″, LD2″, and LD3″. The cathode electrode CE″ may be entirely disposed on the first bank BNK1, the first to third light emitting elements LD1″, LD2″, and LD3″, and the overcoat layer OCL. The cathode electrode CE″ may contact a top surface of a light emitting stack structure EST″ of each of the first to third light emitting elements LD1″, LD2″, and LD3″. The cathode electrode CE″ may be electrically connected to the second power voltage node VSSN shown in FIG. 2. The second power voltage applied to the second power voltage node VSSN may be transferred to the first to third light emitting elements LD1″, LD2″, and LD3″ through the cathode electrode CE″.

The cathode electrode CE″ may be formed substantially transparent or translucent to satisfy a predetermined or selected light transmittance. In embodiments, the cathode electrode CE″ may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the cathode CE″ is not limited thereto.

The capping layer CPL may be disposed over the cathode electrode CE″. The capping layer CPL may protect components disposed under the capping layer CPL, such as the cathode electrode CE″ and the first to third light emitting elements LD1″, LD2″, and LD3″, from external moisture, humidity, and the like. The capping layer CPL may include at least one of silicon nitride, silicon oxide, silicon oxynitride, and a metal oxide such as aluminum oxide. However, the material of the capping layer CPL is not limited thereto.

The light functional layer LFL may be disposed on the capping layer CPL. The light functional layer LFL may include the second bank BNK2, the reflective layer RFL, a third passivation layer PSV3, first and second light conversion patterns CCP1 and CCP2, a light scattering pattern LSP, a low refractive layer LRL, and a color filter layer CFL.

The second bank BNK2 may be disposed on the capping layer CPL. The second bank BNK2 may overlap the first bank BNK1. The second bank BNK2 may have the second openings OP2 overlapping the first openings OP1.

The second bank BNK2 may be configured to include a light blocking material, to prevent light mixture between adjacent sub-pixels and the first to third sub-pixels SP1″, SP2″, and SP3″. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the second openings OP2. The reflective layer RFL may be configured to reflect incident light, and accordingly, light emission efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

It may be understood that emission areas EMA and a non-emission area NEMA of the first to third sub-pixels SP1″, SP2″, and SP3″ are defined by the second bank BNK2. An area overlapping the second bank BNK2 may correspond to the non-emission area NEMA. Areas overlapping the second openings OP2 of the second bank BNK2 may correspond to the emission areas EMA.

On a capping layer CPL, the third passivation layer PSV3 may be disposed in the second openings OP2. The third passivation layer PSV3 may protect components disposed under the third passivation layer PSV3, and provide a flat top surface. The third passivation layer PSV3 and at least one of the first and second passivation layers PSV1 and PSV2 may include a same material, but embodiments are not limited thereto.

On the third passivation layer PSV3, the first and second light conversion patterns CCP1 and CCP2 and the light scattering pattern LSP may be disposed in the second openings OP2.

The first and second light conversion patterns CCP1 and CCP2 and the light scattering pattern LSP may include color conversion particles and/or light scattering particles. The color conversion particles may convert incident light into light of another color by changing a wavelength of the incident light. Also, the color conversion particles may scatter incident light. In embodiments, the color conversion particles may be quantum dots. The light scattering particles may scatter incident light.

In embodiments, the first to third light emitting elements LD1″, LD2″, and LD3″ may be configured to emit light of a blue color. The first light conversion pattern CCP1 may include first color conversion particles QD1 configured to convert light of the blue color into light of a red color. The second light conversion pattern CCP2 may include second color conversion particles QD2 configured to convert light of the blue color into light of a green color. The light scattering pattern LSP may include light scattering particles SCT which scatter light of the blue color so as to improve light emission efficiency. Accordingly, the first to third sub-pixels SP1″, SP2″, and SP3″ may be provided as a red sub-pixel, a green sub-pixel, and a blue sub-pixel, respectively. In embodiments, at least one of the first and second light conversion patterns CCP1 and CCP2 and the light scattering pattern LSP may further include color conversion patterns which convert light of the blue color into light of a white color.

As described with reference to FIGS. 22 and 23, in case that the first to third light emitting elements LD1″, LD2″, and LD3″ are configured to emit light of the same color (e.g., the blue color), numbers, shapes, and contact areas of pillar structures PS″ of the respective first to third light emitting elements LD1″, LD2″, and LD3″ may be substantially the same.

In embodiments, the first to third light emitting elements LD1″, LD2″, and LD3″ may be configured to emit lights of the red color, the green color, and the blue color, respectively. Each of the first and second light conversion patterns CCP1 and CCP2 and the light scattering pattern LSP may include the light scattering particles SCT. As such, the particles included in the first and second light conversion patterns CCP1 and CCP2 and the light scattering pattern LSP may be variously changed according to colors of lights emitted from the first to third light emitting elements LD1″, LD2″, and LD3″.

As described with reference to FIGS. 22 and 23, in case that the first to third light emitting elements LD1″, LD2″, and LD3″ are configured to emit lights of different colors, numbers, shapes, and contact areas of pillar structures PS″ of the respective first to third light emitting elements LD1″, LD2″, and LD3″ may be different from one another.

In embodiments, the first and second light conversion patterns CCP1 and CCP2 and the light scattering pattern LSP may be omitted.

The low refractive layer LRL may be disposed on the second bank BNK2, the reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. The low refractive layer LRL may be configured to refract or totally reflect light according to an incident angle of the corresponding light. The low refractive layer LRL may again provide light passing through the first and second light conversion patterns CCP1 and CCP2 and the light scattering pattern LSP to the first and second light conversion patterns CCP1 and CCP2 and the light scattering pattern LSP, and accordingly, the light conversion efficiency and light scattering efficiency of the first and second light conversion patterns CCP1 and CCP2 and the light scattering pattern LSP can be improved. In embodiments, the low refractive layer LRL may be omitted in an area corresponding to the third sub-pixel SP3″.

The color filter layer CFL may be disposed on the low refractive layer LRL. The color filter layer CFL may include the first to third color filters CF1, CF2, and CF3 and light blocking patterns LBP.

The first to third color filters CF1, CF2, and CF3 may overlap the first and second light conversion patterns CCP1 and CCP2 and the light scattering pattern LSP, respectively. Each of the first to third color filters CF1, CF2, and CF3 may allow light in a desired wavelength range to be selectively transmitted through the color filter. In case that the first sub-pixel SP1″ is a red sub-pixel, the first color filter CF1 may include a red color filter. In case that the second sub-pixel SP2″ is a green sub-pixel, the second color filter CF2 may include a green color filter. In case that the third sub-pixel SP3″ is a blue sub-pixel, the third color filter CF3 may include a blue color filter. The first to third color filters CF1, CF2, and CF3 may have a refractive index higher than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas (or light output areas) EMA and the non-emission area NEMA of the first and second sub-pixels SP1″, SP2″, and SP3″ are defined by the light blocking patterns LBP. An area overlapping the light blocking patterns LBP may correspond to the non-emission area NEMA. Areas not overlapping the light blocking patterns LBP may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1, CF2, and CF3. For example, each of the light blocking patterns LBP may be formed as the first to third color filters CF1, CF2, and CF3 overlap each other. In another example, a light blocking pattern between the first and second color filters CF1 and CF2 among the light blocking patterns LBP may be formed as a multi-layer in which the first and second color filters CF1 and CF2 overlap each other, and a light blocking pattern between the second and third color filters CF2 and CF3 among the light blocking patterns LBP may be formed as a multi-layer in which the second and third color filters CF2 and CF3 overlap each other. A light blocking pattern between the first color filter CF1 and a third color filter CF3 of an adjacent pixel may be formed as a multi-layer in which the first and third color filters CF1 and CF3 overlap each other. As such, each of the first to third color filters CF1, CF2, and CF3 may extend to the non-emission area NEMA to form the light blocking patterns LBP.

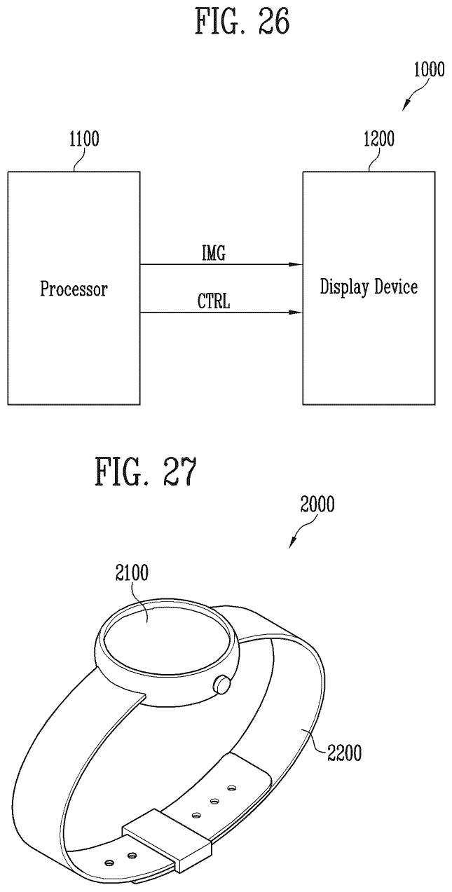

FIG. 26 is a schematic block diagram illustrating a display system in accordance with an embodiment of the disclosure.

Referring to FIG. 26, a display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be configured substantially identical (or similar) to the display device DD described with reference to FIG. 1. The image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

FIGS. 27 to 30 are schematic perspective views illustrating application examples of the display system shown in FIG. 26.

Referring to FIG. 27, the display system 1000 shown in FIG. 26 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100, so that image data including time information can be provided to the user.

Referring to FIG. 28, the display system 1000 shown in FIG. 26 may be applied to an automotive display system 3000. The automotive display system 3000 may include a computing system provided at the inside/outside of a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat display 3600, which are provided in the vehicle.

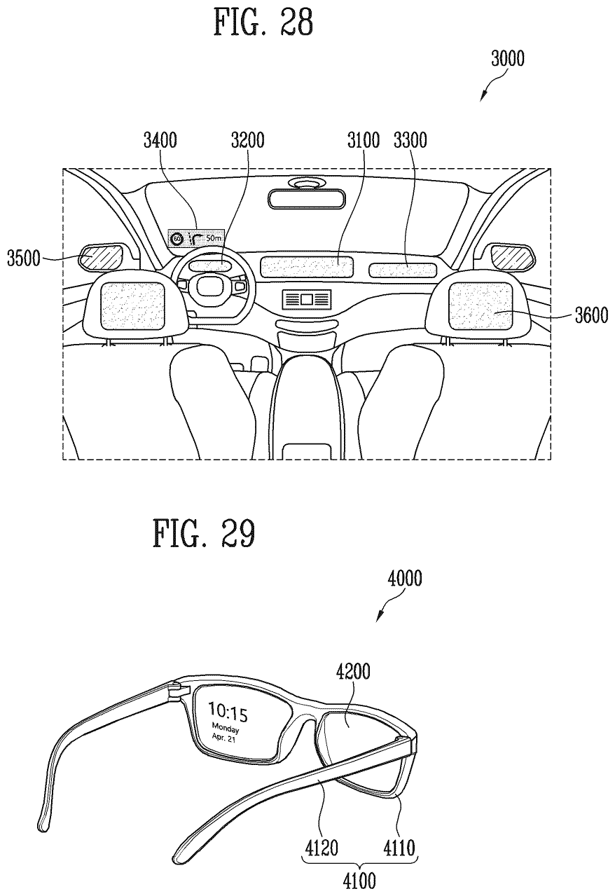

Referring to FIG. 29, the display system 1000 shown in FIG. 26 may be applied to smart glasses 4000. The smart glasses 4000 are a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. A projector for outputting light, a processor for controlling a light signal, and the like may be built in the frame 4100.

The lens part 4200 may be an optical member which allows light to be transmitted through the optical member or allows light to be reflected by the optical member. For example, the lens part 4200 may include glass, transparent synthetic resin, and the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

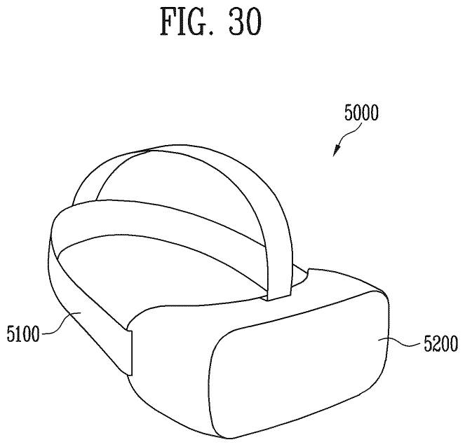

Referring to FIG. 30, the display system 1000 shown in FIG. 26 may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

In accordance with the disclosure, the injection area of current injected through pillar structures can be adjusted such that the light emitting element can emit light with optimum efficiency. Thus, the light emission efficiency of the light emitting element can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A light emitting element, comprising:
pillar structures including a first semiconductor layer and an auxiliary layer disposed on the first semiconductor layer, the pillar structures being spaced apart from each other;
an active layer disposed on the pillar structures;
a second semiconductor layer disposed on the active layer;
a first bonding electrode disposed below the pillar structures, the first bonding electrode being electrically connected to the first semiconductor layer; and
a second bonding electrode disposed below the second semiconductor layer, the second bonding electrode being electrically connected to a non-overlapping surface of a bottom surface of the second semiconductor layer, which does not overlap the pillar structures and the active layer.

2. The light emitting element of claim 1, further comprising:
an insulative film covering at least a portion of an outer circumferential surface of a light emitting stack structure defined by the active layer and the second semiconductor layer.

3. The light emitting element of claim 2, wherein
the insulative film exposes bottom surfaces of the pillar structures, and
the first bonding electrode electrically contacts the bottom surfaces of the pillar structures.

4. The light emitting element of claim 2, wherein
the insulative film defines a penetration hole exposing at least a portion of the non-overlapping surface, and
the second bonding electrode electrically contacts the non-overlapping surface exposed by the penetration hole.

5. The light emitting element of claim 4, wherein an area of the penetration hole in plan view is smaller than an area of the second bonding electrode in plan view.

6. The light emitting element of claim 2, wherein the insulative film includes a first insulative film and a second insulative film covering the first insulative film.

7. The light emitting element of claim 6, wherein side surfaces of the pillar structures are covered by the first insulative film.

8. The light emitting element of claim 6, wherein the second insulative film has a multi-layer structure.

9. The light emitting element of claim 1, wherein
the first semiconductor layer has a first polarity, and
the second semiconductor layer has a second polarity different from the first polarity.

10. The light emitting element of claim 1, wherein a thickness of the auxiliary layer is smaller than a thickness of the first semiconductor layer.

11. The light emitting element of claim 10, wherein the thickness of the auxiliary layer is in a range of about 1 nm to about 100 nm.

12. The light emitting element of claim 1, wherein
the second semiconductor layer includes a first doping portion disposed on the active layer and a second doping portion disposed on the first doping portion, and
a first average doping concentration at the first doping portion is higher than a second average doping concentration at the second doping portion.

13. A light emitting element, comprising:
pillar structures including a first semiconductor layer and an auxiliary layer disposed on the first semiconductor layer, the pillar structures being spaced apart from each other;
an active layer disposed on the pillar structures;
a second semiconductor layer disposed on the active layer; and
a bonding electrode disposed below the pillar structures, the bonding electrode being electrically connected to the first semiconductor layer.

14. The light emitting element of claim 13, further comprising:
an insulative film covering at least a portion of an outer circumferential surface of a light emitting stack structure defined by the active layer and the second semiconductor layer.

15. The light emitting element of claim 14, wherein the insulative film exposes a top surface of the light emitting stack structure.

16. The light emitting element of claim 14, wherein
the insulative film exposes bottom surfaces of the pillar structures, and
the bonding electrode electrically contacts the bottom surfaces of the pillar structures.

17. The light emitting element of claim 14, wherein the insulative film includes a first insulative film and a second insulative film covering the first insulative film.

18. The light emitting element of claim 17, wherein side surfaces of the pillar structures are covered by the first insulative film.

19. The light emitting element of claim 17, wherein the second insulative film has a multi-layer structure.

20. The light emitting element of claim 13, wherein a thickness of the auxiliary layer is smaller than a thickness of the first semiconductor layer.
